(19) United States
(12) Patent Application Publication
(10) Pub. No.: US 2026/0198153 A9
(43) Pub. Date: Jul. 9, 2026

(54) OPTOELECTRONIC MODULE

(71) Applicant: ams-OSRAM International GmbH, Regensburg (DE)

(72) Inventor: Siegfried HERRMANN, Neukirchen (DE)

(21) Appl. No.: 18/864,839

(22) PCT Filed: May 15, 2023
(86) PCT No.: PCT/EP2023/062941

§ 371 Date: Nov. 11, 2024

(30) Foreign Application Priority Data
May 19, 2022 (DE) 10 2022 112 637.4

(51) Int. Cl. H10H 29/20; H01L 25/16; H10F 55/255; H10H 29/85

(52) U.S. Cl. CPC H10H 29/20; H10F 55/255; H10H 29/857; H10W 90/00

(57) ABSTRACT

The invention relates to an optoelectronic module. The optoelectronic module comprises an optoelectronic component structure for light emission with at least one optoelectronic component, an electronic semiconductor chip for controlling an operation of the optoelectronic component structure and a carrier. The optoelectronic component structure is arranged at least on the electronic semiconductor chip. The optoelectronic component structure is designed to bring about a light emission in a region covering the electronic semiconductor chip and in a region not covering the electronic semiconductor chip and lateral to the electronic semiconductor chip.

The present invention relates to an optoelectronic module comprising an optoelectronic component structure for light emission with at least one optoelectronic component, and an electronic semiconductor chip for controlling operation of the optoelectronic component structure.

This patent application claims the priority of German patent application 10 2022 112 637.4, the disclosure content of which is hereby incorporated by reference thereto.

An optoelectronic module for light emission may comprise an optoelectronic component structure with one or more light-emitting optoelectronic components, and an electronic semiconductor chip for controlling operation of the optoelectronic component structure. One possible field of use is a headlight of an adaptive lighting system used in the automotive sector (AFS, adaptive front-lighting system). The light emission may be effected by a pixelated light-emitting semiconductor chip which is arranged on the electronic semiconductor chip and is contacted by the latter (μAFS, micro-structured adaptive front-lighting system). In this case, the light emission may occur in a region in which the pixelated light-emitting semiconductor chip covers the electronic semiconductor chip. The two semiconductor chips may be coordinated with one another with regard to the dimensions and contact elements used for contacting. Geometric changes in the light emission may be effected by design changes of the pixelated semiconductor chip or an addition of further light-emitting components mounted on the electronic semiconductor chip. This may be associated in each case with design changes of the electronic semiconductor chip, and therefore with a high complexity and costs.

The object of the present invention is to specify an improved optoelectronic module which makes possible a high configuration flexibility.

This object is achieved by way of an optoelectronic module as claimed in claim 1. Further advantageous embodiments of the invention are specified in the dependent claims.

In accordance with one aspect of the invention, an optoelectronic module is proposed. The optoelectronic module comprises an optoelectronic component structure for light emission with at least one optoelectronic component, an electronic semiconductor chip for controlling operation of the optoelectronic component structure, and a carrier. The optoelectronic component structure is arranged at least on the electronic semiconductor chip. The optoelectronic component structure is configured to cause light emission in a region covering the electronic semiconductor chip and in a region not covering the electronic semiconductor chip and lateral to the electronic semiconductor chip.

The proposed optoelectronic module differs from a conventional configuration in that light emission by the optoelectronic component structure is not just restricted to the region of the electronic semiconductor chip used for control purposes, but rather is additionally extended to a region lateral to the electronic semiconductor chip. In this respect, emission of light radiation may take place in a region in which the electronic semiconductor chip is covered by the optoelectronic component structure, and in a further region lateral to the electronic semiconductor chip, in which the electronic semiconductor chip is not covered by the component structure. This applies as seen in a plan view of a front or light emission side of the optoelectronic module, from which the light radiation may be emitted.

A high configuration freedom and flexibility with regard to production of the optoelectronic module are possible by virtue of this approach. With in each case the same, for example standardized, configuration of the electronic semiconductor chip, and using different configurations of the optoelectronic component structure and optionally of the carrier, different configurations of the optoelectronic module may be realized here in a flexible manner. This approach is not associated with changes in the electronic semiconductor chip associated with a high complexity, with the result that a cost saving as possible. Moreover, an electronic semiconductor chip comprising compact dimensions may be employed, which is likewise cost-effective. Different configurations of the optoelectronic component structure may be attained for example by way of different configurations, numbers, shapes and/or sizes of the optoelectronic components used in each case. For example, different micro-LED technologies may be combined here.

Further possible details and embodiments which may be considered for the optoelectronic module are described in greater detail below.

Depending on the number of optoelectronic components used for light emission, the optoelectronic component structure may comprise one or more emission regions arranged next to one another, in which the light emission may take place. In this case, as seen in a plan view of a light emission side of the optoelectronic module, one or more emission regions may at least partly cover the electronic semiconductor chip and also the carrier lateral to the electronic semiconductor chip.

The electronic semiconductor chip used for controlling operation of the optoelectronic component structure may be a CMOS chip (complementary metal oxide semiconductor) and/or an application-specific integrated circuit or an ASIC chip.

The electronic semiconductor chip, the optoelectronic component structure or the at least one optoelectronic component thereof and optionally the carrier may comprise contact elements. The contact elements may be embodied in metallic fashion. In this case, contact elements of the optoelectronic component structure may be electrically connected to contact elements of the electronic semiconductor chip and optionally of the carrier. In this way, electrical potentials may be applied to the contact elements of the optoelectronic component structure, whereby the component structure may be electrically supplied in a suitable manner during operation. The electrical potentials may be generated by the electronic semiconductor chip. If not only the electronic semiconductor chip but also the carrier comprises one or more contact elements, the contact element(s) of the carrier may be electrically connected to the electronic semiconductor chip in a suitable manner. For this purpose, the carrier may comprise one or more conductor structures, such as conductor tracks, for example, which may be electrically connected to the electronic semiconductor chip. Contact elements of the electronic semiconductor chip and of the carrier which are used for contacting the optoelectronic component structure may be arranged in a common horizontal plane, and thereby form a contacting plane.

The optoelectronic component structure may be arranged not only on the electronic semiconductor chip but also on the carrier. In this case, the component structure may be connected to the electronic semiconductor chip and—in the case of an arrangement on the carrier as well—to the carrier. The respective connection may be an electrically conductive and thermal connection, or an only thermally conductive connection, and may be produced by way of a connection medium. A solder or an (electrically conductive) adhesive may be used for this. With regard to an electrical connection, rear-side contact elements of the component structure may be connected to opposite further contact elements, which may be part of the electronic semiconductor chip and optionally of the carrier. By way of an electrically conductive connection and also an only thermally conductive connection, heat dissipation may be achieved during operation of the optoelectronic component structure.

In regard to a purely thermally conductive connection, the use of a solder as connection medium may likewise be considered. In order to preclude an unwanted electrical connection from occurring here, an insulation layer may be provided in the region of the thermal coupling. The insulation layer may be part of an optoelectronic component of the optoelectronic component structure.

Further possible configurations of the optoelectronic module and of the optoelectronic component structure and also of the at least one optoelectronic component thereof are described below. In this case, features and details mentioned with regard to one configuration may also be applied with regard to another explained configuration and a plurality of configurations may be combined with one another. By way of example, the optoelectronic component structure may comprise a plurality of optoelectronic components for which different configurations from among those mentioned below are provided.

The optoelectronic component structure comprises at least one optoelectronic component. This may involve a light-emitting semiconductor chip. The semiconductor chip may be a thin-film chip, and, besides contact elements, may comprise a light-emitting semiconductor layer sequence and optionally a conversion layer for radiation conversion. The semiconductor layer sequence may generate a primary light radiation, which may be at least partly converted into a secondary light radiation by the conversion layer. A mixed radiation comprising the primary light radiation and secondary light radiation may be emitted as a result. The use of a pixelated light-emitting semiconductor chip is also possible. Such a monolithic semiconductor chip may comprise separately drivable pixels arranged next to one another for light emission purposes.

In one configuration of the optoelectronic component structure comprising a plurality of optoelectronic components, a plurality of light-emitting semiconductor chips may be employed. A light-emitting semiconductor chip may furthermore be realized in the form of a light-emitting diode chip or LED chip. The use of a laser diode chip or a surface emitter (VCSEL, vertical-cavity surface emitting laser) is also possible. Instead of one or more semiconductor chips, the use of one or more packaged optoelectronic components is also conceivable, which may comprise one or more (light-emitting) semiconductor chips provided with a package.

In one configuration of the optoelectronic component structure comprising a plurality of light-emitting components or semiconductor chips, these may be configured, depending on the application, for generating light radiations comprising a white color, for example, or else for generating different-colored light radiations.

In the case of an optoelectronic component or semiconductor chip configured for light emission, the emission of a light radiation may take place by way of or substantially by way of a front side of the component. The relevant component may comprise contact elements for contacting at an opposite rear side. This configuration may also be referred to as a flip-chip or a horizontal configuration. A vertical configuration comprising contact elements present at both sides, i.e. at the front side and at the rear side, is also possible.

In a further embodiment, the optoelectronic component structure comprises an optoelectronic component which is arranged on the electronic semiconductor chip and the carrier and covers the electronic semiconductor chip and the carrier lateral to the electronic semiconductor chip in a region. In this way, the relevant optoelectronic component may cause light emission in a continuous region in which the optoelectronic component covers the electronic semiconductor chip and also the carrier lateral to the electronic semiconductor chip.

In a further embodiment, the optoelectronic component structure comprises an optoelectronic component which projects laterally beyond the electronic semiconductor chip, thereby covers the carrier in a region lateral to the electronic semiconductor chip and is thermally or only thermally conductively connected to the carrier in this region. A thermal energy that occurs during operation of the relevant optoelectronic component may thereby be reliably dissipated by way of the carrier. The optoelectronic component may furthermore be arranged on the electronic semiconductor chip and electrically contacted by the latter, such that heat may also be dissipated by way of the electronic semiconductor chip.

In a further embodiment, the optoelectronic component structure comprises an optoelectronic component which is arranged at least on the electronic semiconductor chip and covers at least the electronic semiconductor chip in a region. Furthermore, the optoelectronic component structure comprises at least one further optoelectronic component which is arranged at least on the carrier and covers at least the carrier in a region lateral to the electronic semiconductor chip. In this configuration, the relevant optoelectronic components may cause light emission in the region of the electronic semiconductor chip and also in a region lateral to the electronic semiconductor chip.

In a further embodiment, the optoelectronic component structure comprises an optoelectronic component with contact elements at a rear side which are electrically connected to opposite contact elements of the electronic semiconductor chip. In this way, electrical potentials suitable for operation may be applied to the contact elements of the relevant optoelectronic component by way of the contact elements of the electronic semiconductor chip that are connected thereto. The electrical connection may be established by way of a connection medium such as a solder or an electrically conductive adhesive. In this configuration, the optoelectronic component may cause light emission in the region of the electronic semiconductor chip and optionally, provided that the component is not just located in the region of the electronic semiconductor chip but rather additionally projects beyond the latter and thereby covers the carrier in a region lateral to the electronic semiconductor chip, also lateral to the electronic semiconductor chip. In this region, the optoelectronic component may be purely thermally conductively connected to the carrier and thereby arranged on the carrier.

In a further embodiment, the optoelectronic component structure comprises an optoelectronic component in the form of a pixelated light-emitting semiconductor chip, such as has already been mentioned above, which is arranged on the electronic semiconductor chip. The pixelated light-emitting semiconductor chip comprises contact elements at a rear side which are electrically connected to opposite contact elements of the electronic semiconductor chip. In this way, electrical potentials suitable for operation may be applied to the contact elements of the pixelated light-emitting semiconductor chip by way of the contact elements of the electronic semiconductor chip that are connected thereto, and in this respect the pixels of the pixelated light-emitting semiconductor chip may be driven for light emission purposes. The electrical connection may be established by way of a connection medium such as a solder or an electrically conductive adhesive.

The pixelated light-emitting semiconductor chip may comprise a semiconductor layer sequence or a semiconductor body with light-emitting regions arranged next to one another. The light-emitting regions may be configured for generating a primary light radiation. The pixelated light-emitting semiconductor chip may furthermore comprise a conversion layer arranged on the semiconductor layer sequence for radiation conversion purposes, by which conversion layer the primary light radiation may be partly converted into a secondary light radiation. A mixed radiation comprising the primary light radiation and secondary light radiation may be emitted during operation. The primary light radiation and secondary light radiation may be a blue light radiation and a yellow light radiation, with the result that overall a white light radiation may be emitted.

The pixels of the pixelated light-emitting semiconductor chip may each be formed by a light-emitting region of the semiconductor layer sequence and a region of the conversion layer through which radiation from the relevant light-emitting region is transmitted during operation. The lateral geometric shape of the pixels may be predefined by the lateral geometric shape of the light-emitting regions.

The rear-side contact elements of the pixelated light-emitting semiconductor chip may comprise separate contact elements each assigned to a light-emitting region and thus pixel. The pixelated light-emitting semiconductor chip may furthermore comprise a continuous contact element at the rear side. The continuous contact element may comprise cutouts with the separate contact elements arranged therein. In a manner corresponding thereto, the electronic semiconductor chip may comprise a continuous contact element with cutouts, and separate contact elements arranged within the cutouts. In this case, the continuous contact element and the separate contact elements of the pixelated light-emitting semiconductor chip may be electrically connected to the continuous contact element and the separate contact elements of the electronic semiconductor chip.

The pixelated light-emitting semiconductor chip may only be arranged in the region of the electronic semiconductor chip or cover the electronic semiconductor chip in a region, so that the pixelated light-emitting semiconductor chip may cause light emission in the region of the electronic semiconductor chip. A configuration is also possible in which light emission may be caused by the pixelated light-emitting semiconductor chip in a region lateral to the electronic semiconductor chip.

To that effect, in accordance with a further embodiment, provision is made for the pixelated light-emitting semiconductor chip to project laterally beyond the electronic semiconductor chip and to comprise at its rear side contact elements which project laterally beyond the electronic semiconductor chip and which are electrically connected to opposite contact elements of the electronic semiconductor chip. In line with the configuration mentioned above, the rear-side and laterally projecting contact elements may comprise or be separate contact elements each assigned to a light-emitting region and thus pixel. The relevant light-emitting regions and pixels may also project laterally beyond the electronic semiconductor chip. The separate contact elements may furthermore comprise an elongate shape. The same applies to associated light-emitting regions and pixels of the pixelated light-emitting semiconductor chip. The pixelated light-emitting semiconductor chip may furthermore comprise a continuous contact element at the rear side. The continuous contact element may likewise project laterally beyond the electronic semiconductor chip, and comprise corresponding cutouts for the separate elongate contact elements.

The pixelated light-emitting semiconductor chip projecting laterally beyond the electronic semiconductor chip may furthermore be configured in such a way that the semiconductor chip comprises pixels present in the region of the electronic semiconductor chip and having for example relatively small dimensions together with associated separate contact elements, and further, elongate pixels projecting beyond the electronic semiconductor chip together with associated separate elongate contact elements.

Furthermore, the pixelated light-emitting semiconductor chip, on account of projecting laterally, may cover the carrier in a region. In this region, the pixelated light-emitting semiconductor chip may be purely thermally conductively connected to the carrier and thereby arranged on the carrier.

It is furthermore conceivable to realize the optoelectronic module with a plurality of or two pixelated light-emitting semiconductor chips arranged next to one another. In this case, a first pixelated light-emitting semiconductor chip may only be mounted in the region of the electronic semiconductor chip, and a second pixelated light-emitting semiconductor chip may be arranged in the region of the electronic semiconductor chip and of the carrier and thereby project laterally beyond the electronic semiconductor chip. Both semiconductor chips may comprise rear-side contact elements contacted by the electronic semiconductor chip in the manner described above, wherein the second semiconductor chip comprises contact elements projecting laterally beyond the electronic semiconductor chip. The first semiconductor chip may comprise pixels having for example relatively small dimensions together with associated separate contact elements, and the second semiconductor chip may comprise elongate pixels projecting beyond the electronic semiconductor chip together with associated separate elongate contact elements.

In a further embodiment, the optoelectronic component structure comprises an optoelectronic component with contact elements at a rear side, of which contact elements one rear-side contact element of the optoelectronic component is electrically connected to an opposite contact element of the electronic semiconductor chip and a further rear-side contact element of the optoelectronic component is electrically connected to an opposite contact element of the carrier. In this way, electrical potentials suitable for operation may be applied to the contact elements of the relevant optoelectronic component by way of the contact elements of the electronic semiconductor chip and of the carrier that are connected thereto. The electrical connection may be established by way of a connection medium such as a solder or an electrically conductive adhesive. In this configuration, the optoelectronic component may bridge the electronic semiconductor chip and the carrier or cover the electronic semiconductor chip and the carrier lateral to the electronic semiconductor chip in a region, and in this respect cause light emission in the region of the electronic semiconductor chip and also lateral thereto.

In a further embodiment, the optoelectronic component structure comprises an optoelectronic component with contact elements at a rear side which are electrically connected to opposite contact elements of the carrier. In this case, electrical potentials suitable for operation may be applied to the contact elements of the relevant optoelectronic component by way of the contact elements of the carrier that are connected thereto. The electrical connection may be established by way of a connection medium such as a solder or an electrically conductive adhesive. In this configuration, the optoelectronic component may cause light emission in a region lateral to the electronic semiconductor chip and optionally, provided that the component covers not only the carrier but also the electronic semiconductor chip in a region, also in the region of the electronic semiconductor chip.

In a further embodiment, the optoelectronic component structure comprises an optoelectronic component with a contact element at a front side and a contact element at a rear side. The rear-side contact element of the optoelectronic component is electrically connected to an opposite contact element of the electronic semiconductor chip and the front-side contact element of the optoelectronic component is electrically connected to a contact element of the carrier. In this way, electrical potentials suitable for operation may be applied to the contact elements of the relevant optoelectronic component by way of the contact elements of the electronic semiconductor chip and of the carrier that are connected thereto. In this configuration, the optoelectronic component may cause light emission in the region of the electronic semiconductor chip and optionally, provided that the component is not just located in the region of the electronic semiconductor chip but rather additionally projects beyond the latter and thereby covers the carrier lateral to the electronic semiconductor chip, also lateral to the electronic semiconductor chip. In this region, the optoelectronic component may be additionally thermally conductively connected to the carrier and thereby arranged on the carrier.

With regard to the aforementioned configuration, the rear-side contact element of the optoelectronic component and the opposite contact element of the electronic semiconductor chip may be connected by way of a connection medium such as a solder or an electrically conductive adhesive. The front-side contact element of the optoelectronic component and the contact element of the carrier may be electrically connected by way of a contact layer. The contact layer may be a planar contact layer, also referred to as PI contact (planar interconnect). Furthermore, the contact layer may be transparent, and for this purpose may be formed from indium tin oxide (ITO), for example.

Besides contact elements for operation of the optoelectronic component structure, the electronic semiconductor chip may furthermore comprise contact elements by way of which the electronic semiconductor chip may be supplied with electrical energy and data communication with the electronic semiconductor chip may be carried out. The latter may comprise for example communication of control signals to the electronic semiconductor chip.

The electronic semiconductor chip may comprise contact elements at a front side. In this case, one or more front-side contact elements of the electronic semiconductor chip may be connected to one or more rear-side contact elements of one or more optoelectronic components of the optoelectronic component structure. Moreover, one or more front-side contact elements of the electronic semiconductor chip may be connected to one or more contact elements of the carrier, by virtue of conductor structures of the carrier being employed, inter alia. The front-side contact elements of the electronic semiconductor chip and contact elements of the carrier may form a contacting plane.

In a further embodiment, the electronic semiconductor chip comprises contact elements at a front side and at a rear side. In this configuration, rear-side contact elements of the electronic semiconductor chip may be used for example to supply the electronic semiconductor chip with electrical energy and to carry out data communication with the electronic semiconductor chip. For this purpose, rear-side contact elements of the electronic semiconductor chip may be electrically connected to contact elements and conductor structures of the carrier. It is furthermore possible to use rear-side contact elements of the electronic semiconductor chip for controlling operation of at least one optoelectronic component of the optoelectronic component structure.

To that effect, in accordance with a further embodiment, provision is made for the carrier to comprise extension contact elements which are electrically connected to contact elements of the electronic semiconductor chip at the rear side thereof and project laterally beyond the electronic semiconductor chip at the rear side of the electronic semiconductor chip. The optoelectronic component structure comprises an optoelectronic component which is arranged laterally next to the electronic semiconductor chip and comprises contact elements electrically connected to the extension contact elements, for example at a rear side. By way of this component, light emission lateral to the electronic semiconductor chip may be caused.

With regard to the aforementioned configuration, the optoelectronic module may comprise two mutually offset contacting planes, and thus optoelectronic components arranged in offset planes. One contacting plane may be formed by front-side contact elements of the electronic semiconductor chip and optionally of the carrier, and another contacting plane may be formed by the extension contact elements of the carrier that are located at the rear side of the electronic semiconductor chip. The optoelectronic component contacted by the extension contact elements may be for example a (further) pixelated light-emitting semiconductor chip.

In a further embodiment, the carrier comprises a current feed device for the electrical current supply of an optoelectronic component of the optoelectronic component structure. The current feed device comprises a switching element for activating the current supply, said switching element being electrically connected to the electronic semiconductor chip and controllable by the electronic semiconductor chip. The switching element may be a transistor. In this configuration, high-current operation (for example with a current intensity of a number of amperes) of the optoelectronic component supplied by the current feed device may be made possible by way of the current feed device. Since the electronic semiconductor chip in this case serves only for controlling high-current operation and not for providing the electrical energy, a high-current design of the electronic semiconductor chip is not required. Consequently, the electronic semiconductor chip main be realized cost-effectively. The current feed device of the carrier may comprise conductor structures and contact elements electrically connected to contact elements of the optoelectronic component. During operation, the current feed device may be electrically connected to a suitable current source.

The current feed device of the carrier may also be configured for the electrical current supply of a plurality of optoelectronic components. In this case, the current feed device may comprise a plurality of switching elements for activating the current supply of the plurality of components, said switching elements being controllable by the electronic semiconductor chip.

The electronic semiconductor chip and the carrier may be configured in such a way that a front side of the electronic semiconductor chip terminates flush or substantially with a front side of the carrier that is located laterally next to the electronic semiconductor chip. A level difference between the sides may be in the micrometers range or amount to at most one micrometer. As a result, the optoelectronic component structure may be reliably mounted on the electronic semiconductor chip and the carrier without for example the risk of semiconductor chips breaking.

In a further embodiment, the carrier comprises a depression with the electronic semiconductor chip arranged therein. The depression may comprise a depth such that, as indicated above, a front side of the electronic semiconductor chip terminates (substantially) flush with a front side of the carrier that is located laterally next to the electronic semiconductor chip. If the carrier comprises extension contact elements projecting beyond the electronic semiconductor chip at the rear side of the electronic semiconductor chip, and the optoelectronic component structure comprises an optoelectronic component arranged next to the electronic semiconductor chip and contacted by way of the extension contact elements, the relevant component may likewise be arranged within the depression of the carrier.

The carrier may be configured in integral fashion, or else in multipartite fashion. With regard to the latter variant, in accordance with a further embodiment, the carrier comprises a base part and a further carrier part. The base part may be realized in plate-type fashion. The electronic semiconductor chip is arranged on the base part. The further carrier part is arranged on the base part laterally next to the electronic semiconductor chip. The further carrier part may comprise for example a frame-type shape, and enclose the electronic semiconductor chip. Furthermore, the further carrier part may comprise a thickness such that a front side of the electronic semiconductor chip terminates flush or substantially flush with a front side of the further carrier part that is located laterally next to the electronic semiconductor chip. If, as indicated above, the carrier comprises extension contact elements projecting beyond the electronic semiconductor chip at the rear side of the electronic semiconductor chip, and the optoelectronic component structure comprises an optoelectronic component arranged next to the electronic semiconductor chip and contacted by way of the extension contact elements, the relevant component may likewise be arranged on the base part.

As carrier material or basic material of the carrier, the carrier may comprise a semiconductor material such as silicon, for example. In this case, the carrier may be a silicon chip, for example. It is also possible to use a ceramic or a ceramic material such as silicon nitride, aluminum nitride or aluminum oxide, for example. In this way, the carrier may comprise a thermal expansion behavior which may correspond to that of the electronic semiconductor chip and of the optoelectronic component structure. Furthermore, the carrier may be thermally conductive and enable reliable heat dissipation.

The optoelectronic module may be configured not only for light emission but also for radiation detection. Radiation detection may be employed for example in order to capture ambient light and to control the light emission in a manner coordinated therewith. Furthermore, there is the possibility of carrying out an optical communication based on light emission and radiation detection.

With regard to radiation detection, the optoelectronic component structure may comprise a radiation-detecting optoelectronic component. The radiation-detecting component may be a semiconductor chip comprising a photodiode structure. In line with the configurations described above, the radiation-detecting component may comprise contact elements which are electrically connected to contact elements of the electronic semiconductor chip and/or carrier. In this way, the radiation-detecting component may be suitably electrically connected to the electronic semiconductor chip.

With regard to radiation detection, it may furthermore be conceivable for the carrier to comprise an integrated photodiode. In this case, the integrated photodiode may be electrically connected to the electronic semiconductor chip inter alia by way of one or more conductor structures of the carrier.

The advantageous embodiments and developments of the invention explained above and/or presented in the dependent claims may be applied—apart for example in cases of clear dependencies or incompatible alternatives—individually or else in any desired combination with one another.

The above-described properties, features and advantages of this invention and the way in which they are achieved will become clearer and more clearly understood in association with the following description of exemplary embodiments which are explained in greater detail in association with the schematic drawings, in which:

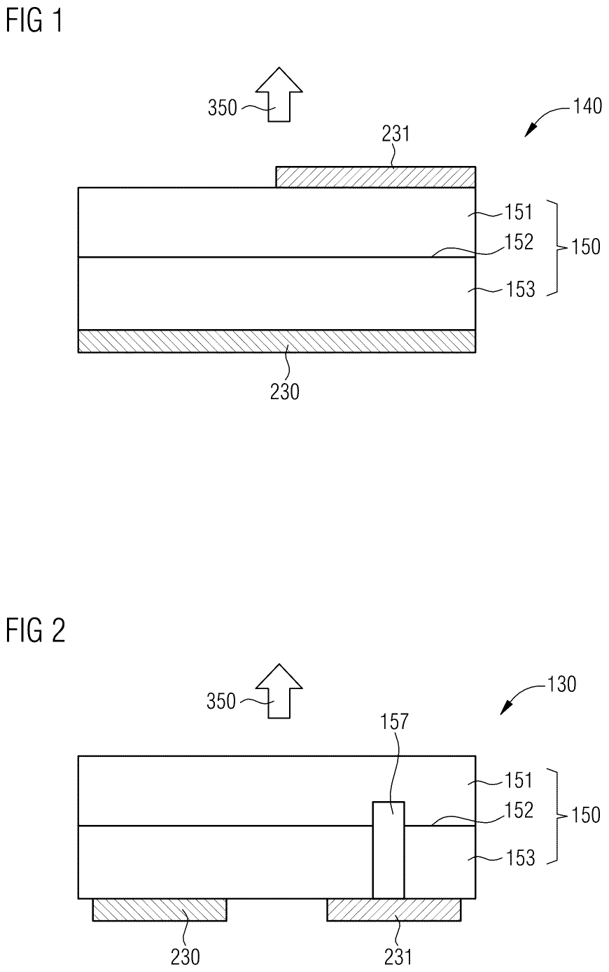

FIGS. 1 to 3 show lateral illustrations of different configurations of light-emitting semiconductor chips;

FIG. 4 shows a lateral illustration of a connection of contact elements by a connection medium;

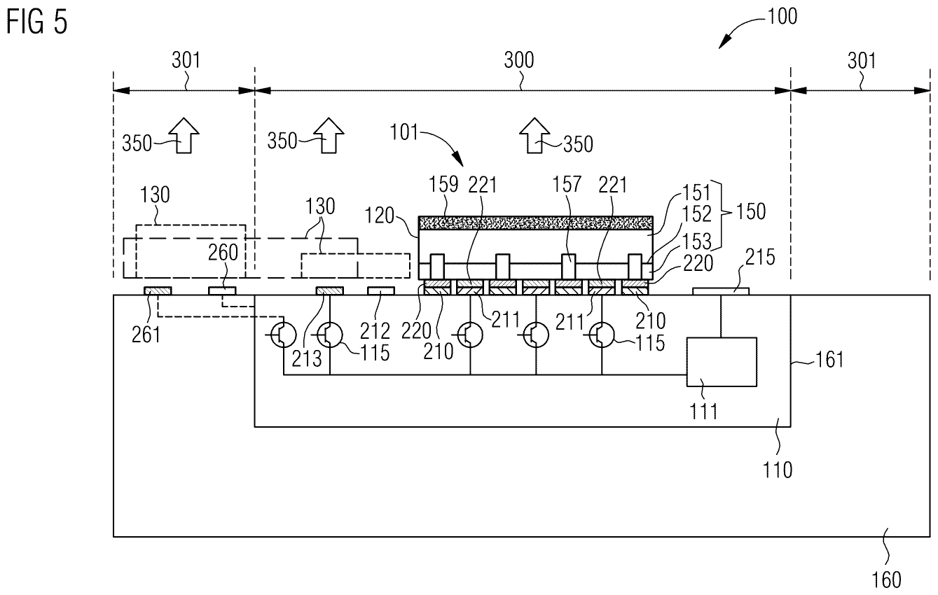

FIG. 5 shows a lateral illustration of one configuration of an optoelectronic module comprising a carrier, an electronic semiconductor chip and an optoelectronic component structure with a pixelated and at least one further light-emitting semiconductor chip, wherein regions are indicated in which light emission may be caused in the region of the electronic semiconductor chip and lateral to the electronic semiconductor chip;

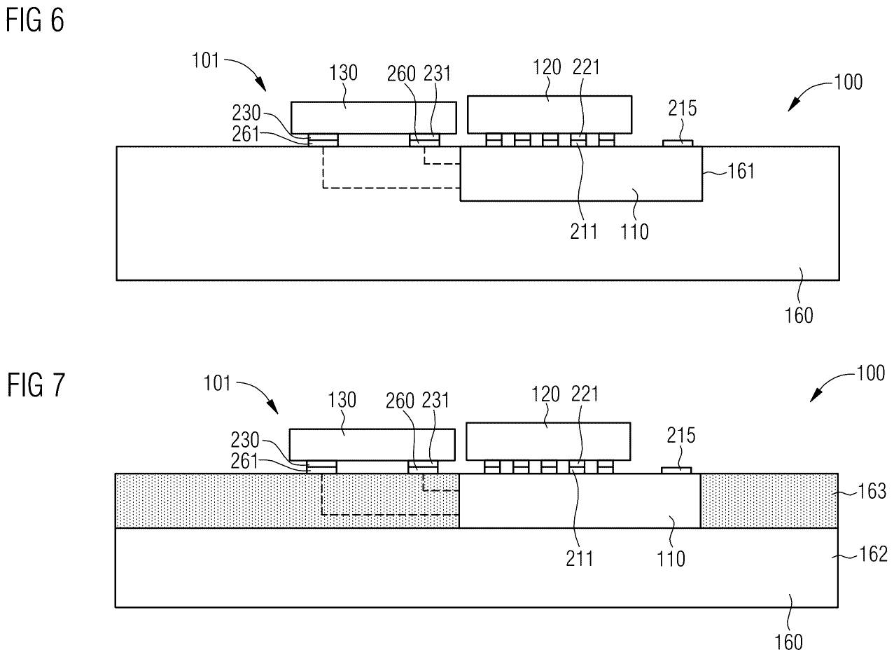

FIGS. 6 to 9 show lateral illustrations of further configurations of the optoelectronic module, wherein the light-emitting semiconductor chips comprise rear-side contact elements connected to contact elements of the electronic semiconductor chip and of the carrier;

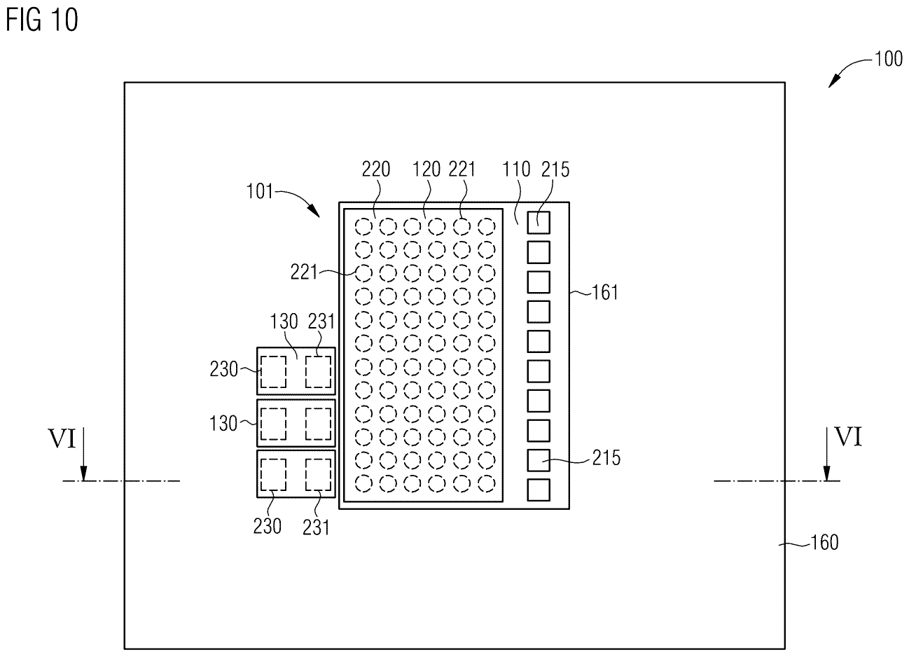

FIGS. 10 to 13 show plan view illustrations of the optoelectronic module corresponding to FIGS. 6 to 9;

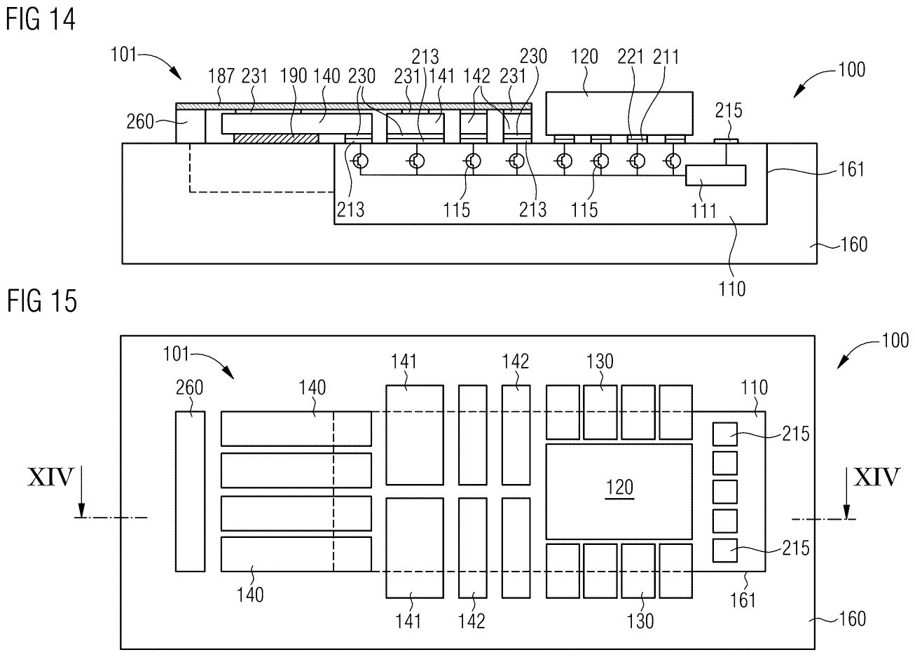

FIGS. 14 and 15 show a lateral illustration and a plan view illustration of a further configuration of the optoelectronic module comprising light-emitting semiconductor chips with front-side contact elements which are connected to a contact layer;

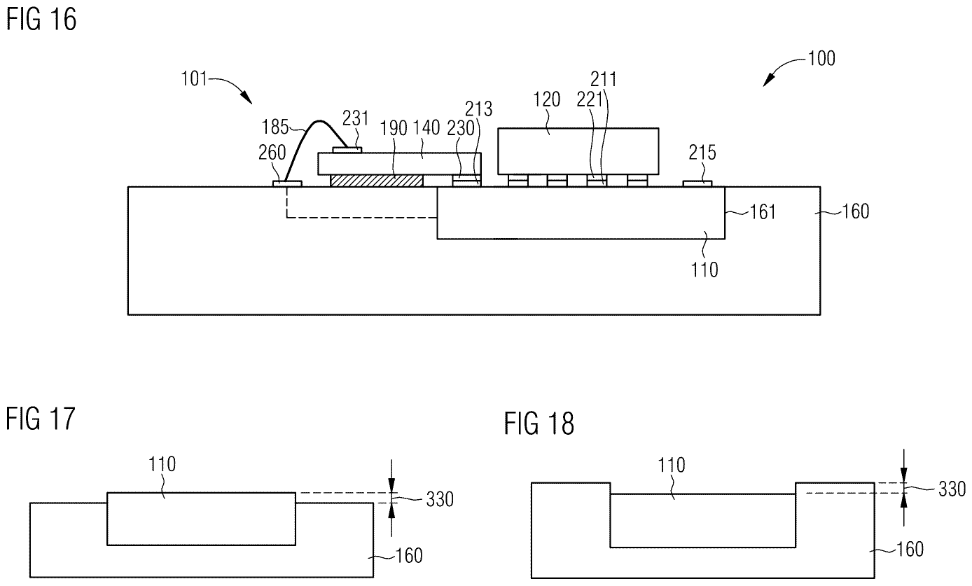

FIG. 16 shows a lateral illustration of a further configuration of the optoelectronic module, wherein contacting of a front-side contact element of a light-emitting semiconductor chip is established by way of a bond wire;

FIGS. 17 and 18 show lateral illustrations of the carrier and of the electronic semiconductor chip, with a level difference being present between these components;

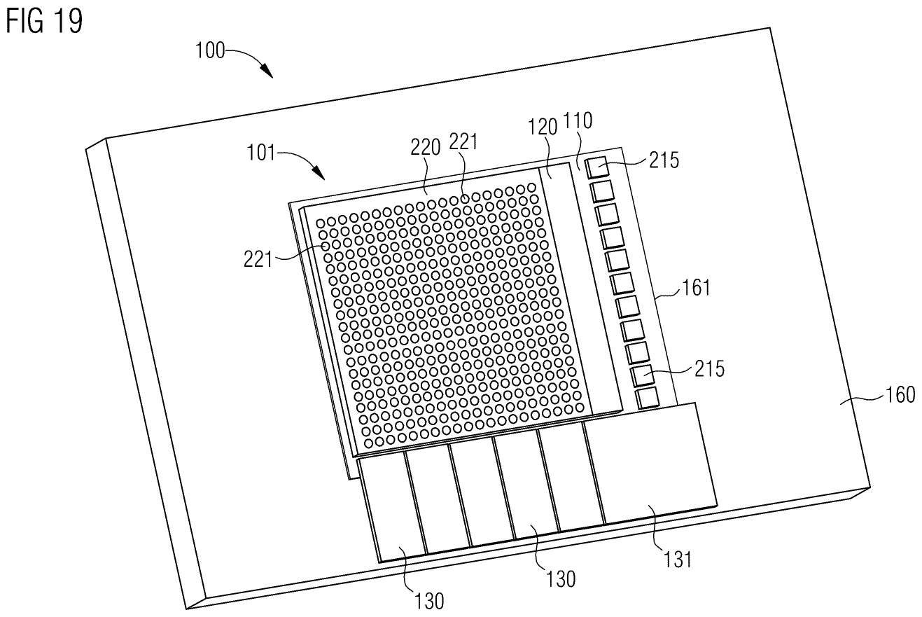

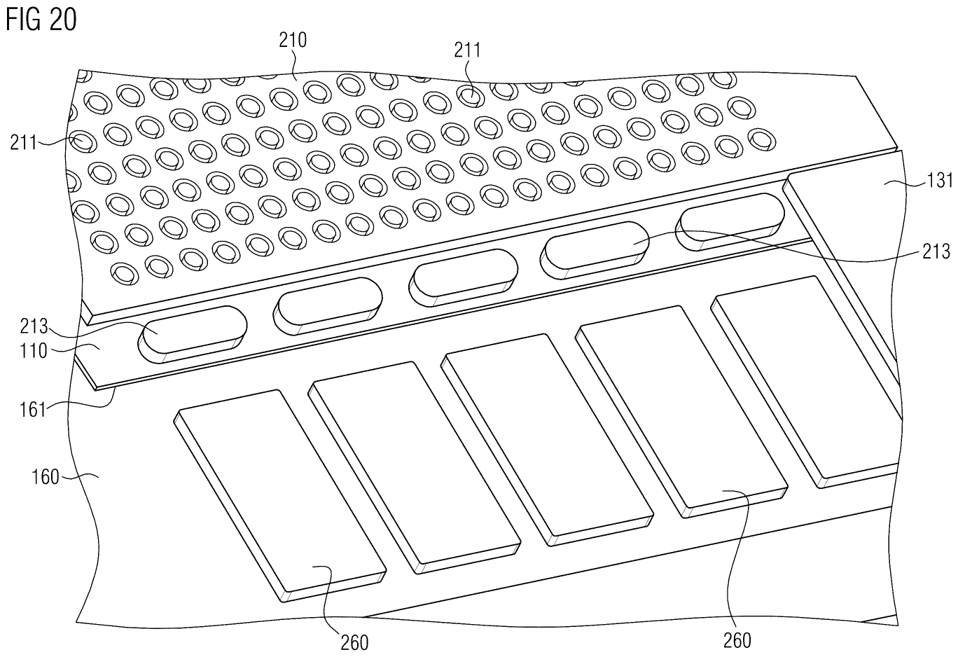

FIGS. 19 and 20 show perspective illustrations of a further configuration of the optoelectronic module comprising a pixelated light-emitting semiconductor chip and further light-emitting semiconductor chips;

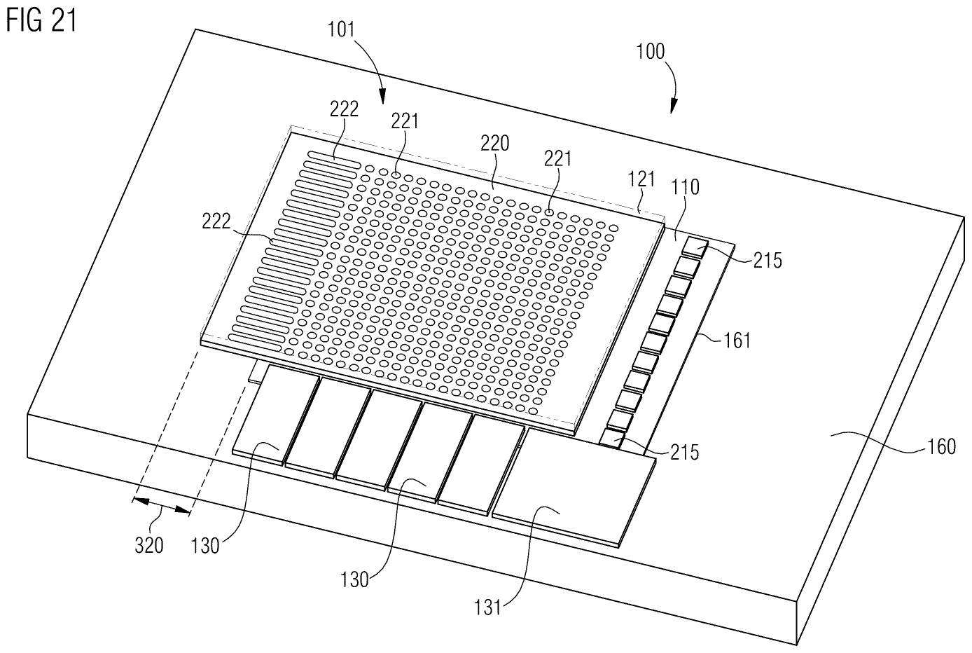

FIGS. 21 to 25 show different illustrations of a further configuration of the optoelectronic module comprising a pixelated light-emitting semiconductor chip projecting laterally beyond the electronic semiconductor chip;

FIG. 26 shows a lateral illustration of a further configuration of the optoelectronic module comprising two pixelated light-emitting semiconductor chips, one pixelated light-emitting semiconductor chip of which projects laterally beyond the electronic semiconductor chip;

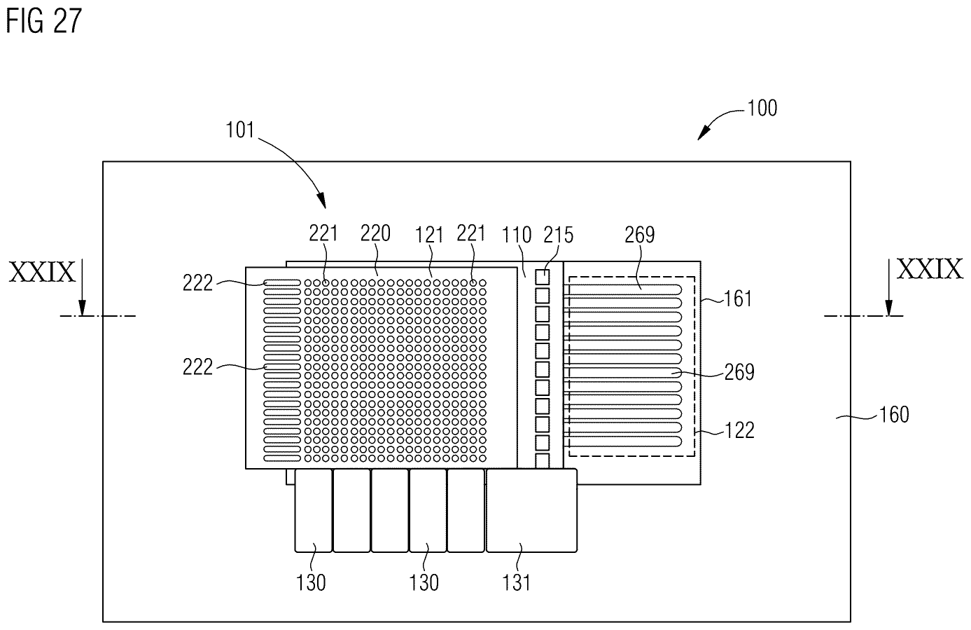

FIGS. 27 to 29 show different illustrations of a further configuration of the optoelectronic module, wherein the carrier comprises extension contact elements projecting laterally beyond the electronic semiconductor chip at the rear side of the electronic semiconductor chip;

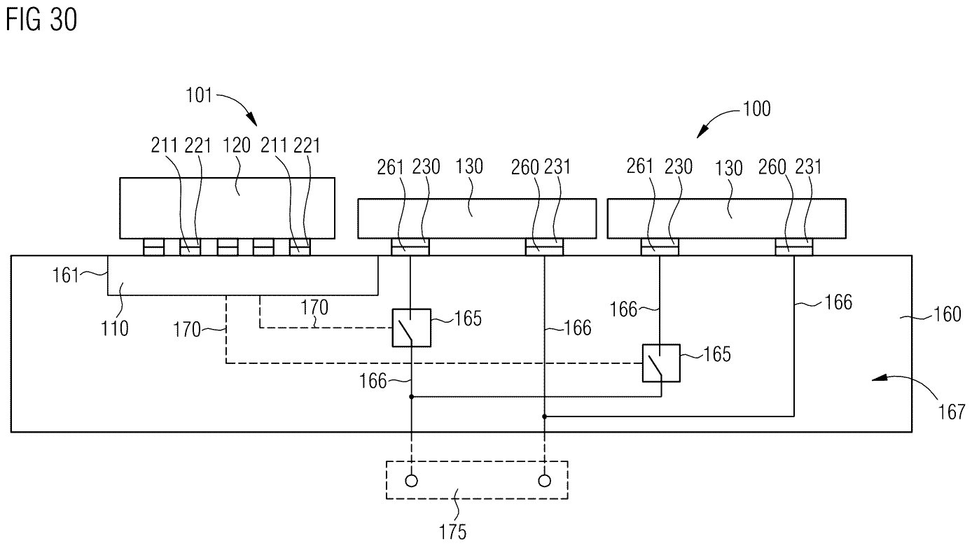

FIG. 30 shows a lateral illustration of a further configuration of the optoelectronic module, wherein the carrier comprises a current feed device for the electrical current supply of light-emitting semiconductor chips arranged on the carrier;

FIG. 31 shows a plan view illustration of a further configuration of the optoelectronic module;

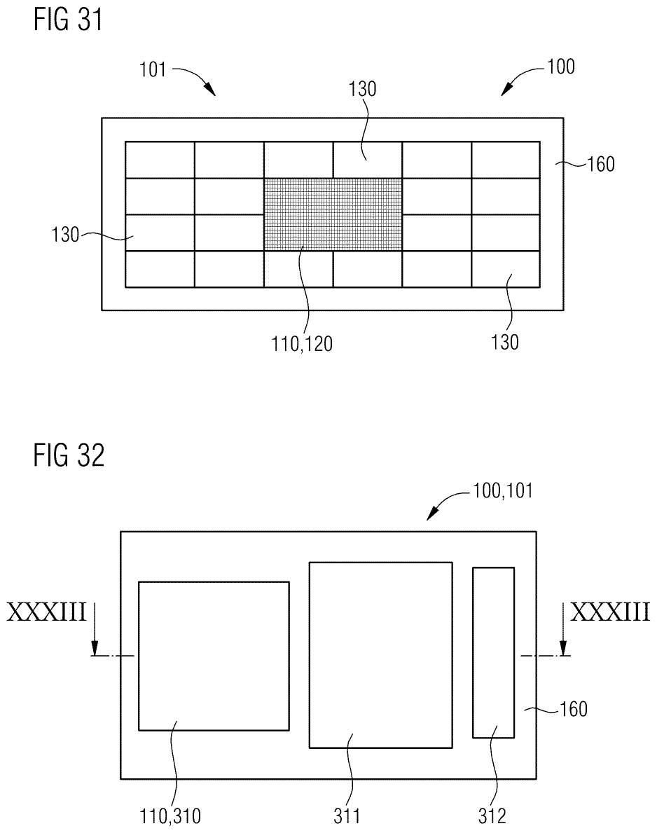

FIG. 32 shows a plan view illustration of a further configuration of the optoelectronic module, indicating regions in which light emission and radiation detection take place; and

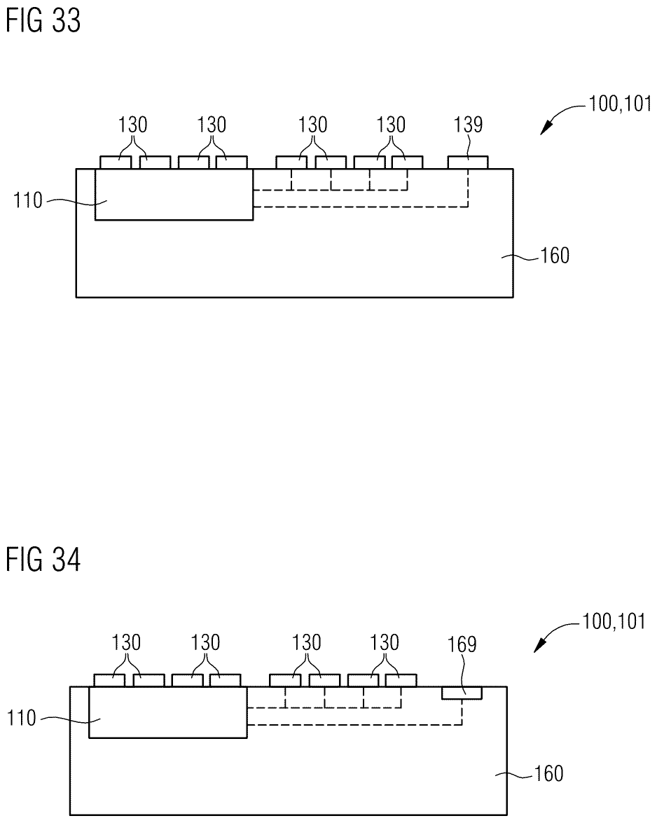

FIGS. 33 and 34 show lateral illustrations of the optoelectronic module from FIG. 32 comprising a radiation-detecting component and an integrated photodiode of the carrier.

With reference to the following schematic figures, a description will be given of possible configurations of an optoelectronic module 100 comprising an optoelectronic component structure 101 for light emission, an electronic semiconductor chip 110 used for control purposes, and a carrier 160. The module 100 is configured to the effect that light radiation may be emitted from the optoelectronic component structure 101 in the region of the electronic semiconductor chip 110 and lateral to the electronic semiconductor chip 110. It is pointed out that the schematic figures may not be true to scale. Therefore, components and structures shown in the figures may be illustrated with exaggerated large size or reduced size for improved understanding.

If the figures show lateral sectional illustrations of the optoelectronic module 100 and the components thereof, reference is made to the fact that sides directed upward are designated as front side, and sides directed downward are designated as rear side. The front side of the module 100 and of light-emitting components furthermore constitutes a light emission side, by way of which the light emission may be effected. The designations front-side and rear-side are used in a corresponding manner for constituent parts present at the respective sides, such as contact elements, for example. Plan view illustrations indicate in part sectional lines relating to sectional planes of associated lateral sectional illustrations. It is supplementarily pointed out that features and details mentioned in relation to one configuration may also be applied in relation to other configurations, and a plurality of configurations and their features may be combined with one another. Corresponding features may be described in detail here only in relation to one configuration.

The optoelectronic component structure 101 comprises at least one light-emitting optoelectronic component, which may be realized in the form of an unpackaged light-emitting semiconductor chip. The relevant semiconductor chip may be a light-emitting diode chip or LED chip, and may comprise contact elements arranged at one side (horizontal configuration) or contact elements arranged at both sides (vertical configuration). Exemplary configurations are illustrated in a lateral sectional view in FIGS. 1 to 3.

FIG. 1 shows a light-emitting semiconductor chip 140 in accordance with a vertical configuration. The semiconductor chip 140 comprises a semiconductor layer sequence 150 comprising a front-side first semiconductor region 151 of a first conduction type, a rear-side second semiconductor region 153 of a second conduction type different than the first conduction type, and an active zone 152 located between the first and second semiconductor regions 151, 153. The first semiconductor region 151 may be n-conducting, and the second semiconductor region 153 may be p-conducting. An inverse configuration comprising a p-conducting first semiconductor region 151 and an n-conducting second semiconductor region 153 is also possible. The active zone 152 serves for generating light, and may be configured in the form of a p-n junction, single quantum well structure or multi-quantum well structure. During operation, a light radiation 350 may be emitted (substantially) by way of the front side of the semiconductor chip 140. The semiconductor chip 140 furthermore comprises two contact elements 230, 231, by way of which the semiconductor chip 140 may be contacted and electrically supplied and have suitable electrical potentials applied to it in order to cause the light emission. The contact element 231 for the electrical connection of the first semiconductor region 151 is located at the front side, and the contact element 230 for the electrical connection of the second semiconductor region 153 is located at the rear side of the semiconductor chip 140. Depending on the conduction type of the semiconductor regions 151, 153, the contact elements 230, 231 may constitute an n-contact and a p-contact (or vice versa).

FIG. 2 shows a light-emitting semiconductor chip 130 in accordance with a horizontal configuration. The semiconductor chip 130 differs from the semiconductor chip 140 in FIG. 1 in that the two contact elements 230, 231 used for the contacting and for the electrical supply of the semiconductor chip 130 are arranged at the rear side thereof. In this configuration, the contact element 230 serves for the electrical connection of the second semiconductor region 153, and the contact element 231 is provided for the electrical connection of the first semiconductor region 151 of the semiconductor layer sequence 150. For this purpose, the semiconductor chip 130 furthermore comprises a via 157 connected to the contact element 231 and extending through the semiconductor layer sequence 150 to the first semiconductor region 151, such that the first semiconductor region 151 may be acted on electrically by way of the contact element 231. During operation, a light radiation 350 may be emitted (substantially) by way of the front side of the semiconductor chip 130.

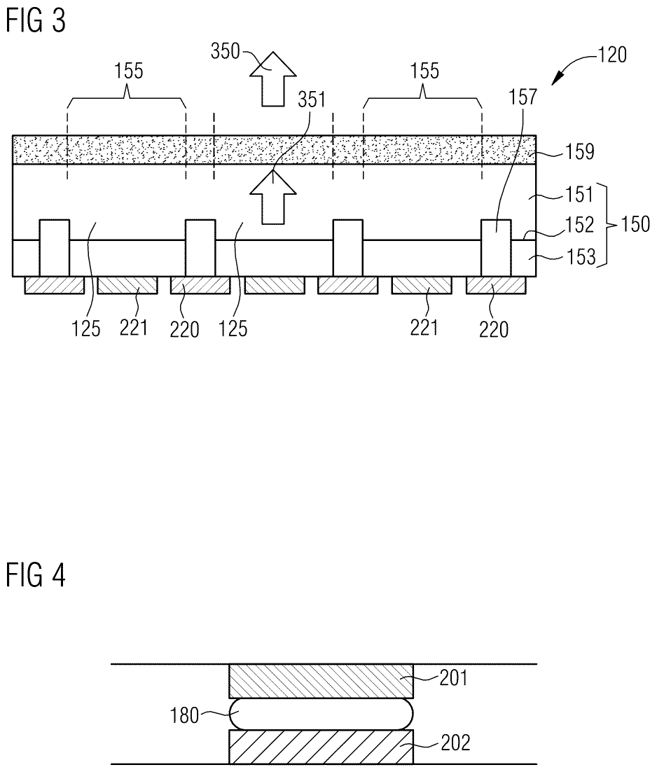

FIG. 3 shows a pixelated configuration of a light-emitting semiconductor chip 120 comprising a plurality of separately drivable light-emitting pixels 155 arranged next to one another. For this purpose, the semiconductor chip 120 or the semiconductor layer sequence 150 thereof comprises a structure comprising a plurality of light-emitting regions 125 arranged next to one another. In this case, the semiconductor layer sequence 150 comprises a front-side continuous first semiconductor region 151 and, in each of the light-emitting regions 125, in each case a rear-side second semiconductor region 153 and an active zone 152 located between the first and the second semiconductor region 153. The active zones 152 are configured for generating light, in the present case for generating a primary light radiation 351.

The pixelated light-emitting semiconductor chip 120 furthermore comprises at the front side a conversion layer 159 for radiation conversion purposes arranged on the semiconductor layer sequence 150. The conversion layer 159 is configured to partly convert the primary light radiation 351 which during operation is generated by the active zones 152 of the light-emitting regions 125 and is emitted in the direction of the conversion layer 159 into a secondary light radiation. The primary light radiation and the secondary light radiation which may be emitted together in the form of a superimposed mixed radiation 350 by the conversion layer 159 may be a blue light radiation and a yellow light radiation.

In this way, a white light radiation 350 may be emitted by way of the front side of the semiconductor chip 120.

In the case of the pixelated light-emitting semiconductor chip 120, each pixel 155 is formed by a light-emitting region 125 of the semiconductor layer sequence 150 and a region of the conversion layer 159 through which the primary radiation 351 is radiated from the relevant light-emitting region 125 during operation. The pixel shapes of the pixels 155 are predefined by the lateral geometric shape of the light-emitting regions 125 of the semiconductor layer sequence 150.

The pixelated light-emitting semiconductor chip 120 furthermore comprises at the rear side a contact structure comprising contact elements 220, 221, by way of which the semiconductor chip 120 may be contacted and electrically supplied. The contact structure comprises separate contact elements 221, which are each assigned to a light-emitting region 125 and thus pixel 155, and which each serve for the electrical connection of a second semiconductor region 153. The contact structure furthermore comprises a continuous contact element 220 provided for the electrical connection of the first semiconductor region 151. Depending on the conduction type of the semiconductor regions 151, 153, the contact elements 220, 221 may constitute an n-contact and a plurality of p-contacts (or vice versa). The continuous contact element 220 comprises cutouts with the contact elements 221 arranged therein. The cutouts of the contact element 220 and the separate contact elements 221 may comprise a circular contour in plan view, with the result that a configuration such as is shown in FIGS. 10 and 19 may be present. Analogously to the semiconductor chip 130 in FIG. 2, the semiconductor chip 120 comprises at least one via 157 connected to the continuous contact element 220 and extending through the semiconductor layer sequence 150 to the first semiconductor region 151, such that the first semiconductor region 151 may be acted on electrically by way of the contact element 220. The via 157 may comprise a continuous shape enclosing the second semiconductor regions 153 and active zones 152. Alternatively, a plurality of separate vias 157 may be formed.

With regard to the semiconductor chips 130, 140 shown in FIGS. 1 and 2 (or else other usable designs-not shown here-of semiconductor chips), there is the possibility of these likewise comprising a conversion layer 159 for radiation conversion purposes at the front side. In this case, a primary light radiation 351 may be generated by the active zone 152 and partly or at least partly converted into a secondary light radiation by the conversion layer 159 (not illustrated).

The semiconductor chips 120, 130, 140 (or else other usable designs of semiconductor chips) may be so-called micro-LEDs or μLEDs. In this case, the semiconductor chips may comprise structures and sizes in the micrometers range.

Rear-side contact elements of components or semiconductor chips of the optoelectronic module 100 may be electrically connected to contact elements opposite them by way of an electrically conductive connection medium 180. This is indicated schematically in FIG. 4 for two contact elements 201, 202, wherein for example the contact element 201 constitutes a rear-side contact element of an optoelectronic component or semiconductor chip, and the contact element 202 constitutes an opposite contact element of the electronic semiconductor chip 100 or of the carrier 160. The connection medium 180 that electrically, and thereby also mechanically and thermally connects the contact elements 201, 202 may be a solder or an electrically conductive adhesive. In subsequent figures, the connection of contact elements which in each case is present and is established by way of the connection medium 180 has been omitted for reasons of clarity.

FIG. 5 shows a lateral sectional illustration of an optoelectronic module 100 in accordance with one possible configuration. The optoelectronic module 100 comprises a carrier 160, an optoelectronic component structure 101 for light emission, and an electronic semiconductor chip 110 for controlling operation of the optoelectronic component structure 101. The carrier 160, which may also be referred to as extension carrier or submount, comprises a depression 161, within which the electronic semiconductor chip 110 is arranged on the carrier 160. The depression 161 comprises a depth such that a front side of the electronic semiconductor chip 110 terminates flush or substantially flush with a front side of the carrier 160 that is located laterally next to the semiconductor chip 110. The optoelectronic component structure 101 mounted on the electronic semiconductor chip 110 and the carrier 160 at least partly covers the electronic semiconductor chip 110 and the carrier 160 lateral to the electronic semiconductor chip 110, such that an emission of light radiation 350 may be caused by the optoelectronic component structure 101 in a region covering the electronic semiconductor chip 110 and also in a region not covering the semiconductor chip 110 lateral to the semiconductor chip 110. For illustration, FIG. 5 supplementarily indicates regions 300, 301 in which the light emission may occur. In this case, the region 300 constitutes a region covering the electronic semiconductor chip 110, and the regions 301 are regions located lateral to the electronic semiconductor chip 110. The regions 301 may also be referred to as extension zone.

The optoelectronic component structure 101 comprises a pixelated light-emitting semiconductor chip 120 and at least one further light-emitting component, for example constructed differently and/or with different lateral dimensions, for example in the form of a semiconductor chip 130, as is indicated with the aid of dashed lines in FIG. 5. The pixelated light-emitting semiconductor chip 120 is arranged on the electronic semiconductor chip 110. By way of the semiconductor chip 120, a light emission may be brought about in the region of the electronic semiconductor chip 110 or in the region 300. This may involve a finely pixelated light emission. The further light-emitting component(s) or semiconductor chip(s) 130 is/are arranged laterally thereto on the electronic semiconductor chip 110 and/or on the carrier substrate 160. By way of the light-emitting component(s) or semiconductor chip(s) 130, a light emission may be brought about in a region lateral to the electronic semiconductor chip 110 or in a region 301 and optionally also in the region of the electronic semiconductor chip 110 or in the region 300. For this purpose, at least one component or semiconductor chip 130 is located at least in a region 301. In this case, the relevant component 130 may also partly cover the electronic semiconductor chip 110 or project into the region 300.

The electronic semiconductor chip 110 serving as a control chip may be a silicon chip, and may be realized as a CMOS chip (complementary metal oxide semiconductor) and in the form of an application-specific integrated circuit (ASIC). The electronic semiconductor chip 110 comprises at the front side a plurality of metallic contact elements 210, 211, 212, 213, 215, of which the contact elements 210, 211, 212, 213 serve for contacting contact elements of the optoelectronic component structure 101 or of a part thereof in order to apply suitable electrical potentials to the relevant contact elements during operation by way of the electronic semiconductor chip 110. The contact elements 215, only one of which is illustrated in the sectional view shown and which may be arranged next to one another in a series (cf. FIG. 10, for example), may be employed inter alia as drive contacts for the external contacting of the electronic semiconductor chip 110 in order to supply the semiconductor chip 110 with electrical energy and to carry out a data communication with the semiconductor chip 110. In this case, for example, control signals may be communicated to the electronic semiconductor chip 110, by way of which signals the operation of the optoelectronic component structure 101 that is controlled by the semiconductor chip 110 may be predefined.

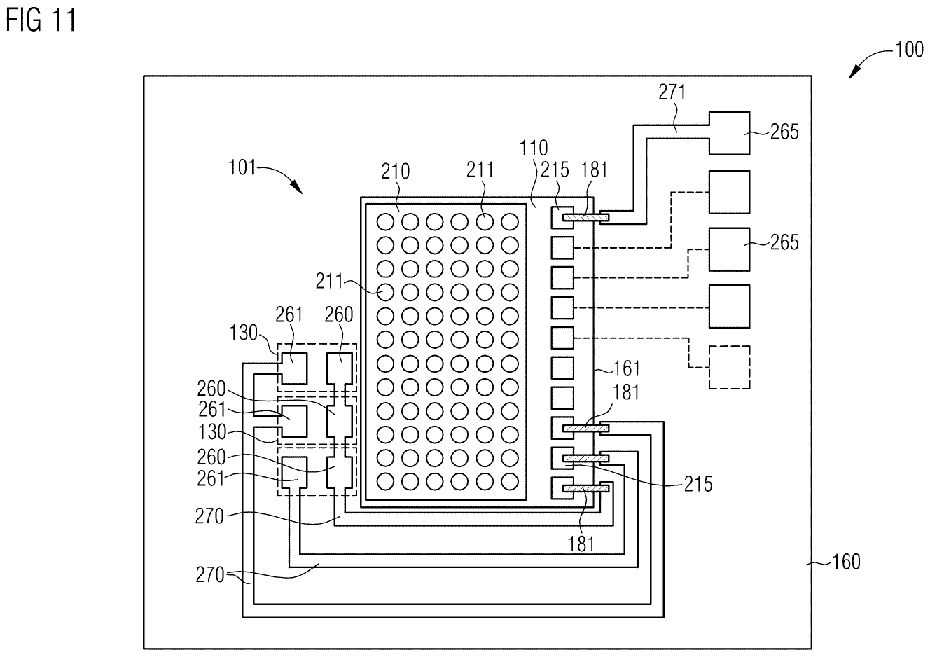

As is shown in FIG. 5, the electronic semiconductor chip 110 comprises contact elements 210, 211 coordinated, with respect to the pixelated light-emitting semiconductor chip 120, with the contact elements 220, 221 thereof, i.e. a plurality of separate contact elements 211 and a continuous contact element 210 comprising cutouts with the separate contact elements 211 arranged therein. In accordance with the contact elements 220, 221 of the semiconductor chip 120, the cutouts of the continuous contact element 210 and the separate contact elements 211 of the electronic semiconductor chip 110 may comprise a circular contour in plan view, with the result that a configuration such as is shown in FIGS. 11 and 20 may be present. Furthermore, the contact element 210 may constitute an n-contact, and the contact elements 211 may constitute p-contacts (or vice versa). The mutually opposite continuous contact elements 210, 220 and separate contact elements 211, 221 of the two semiconductor chips 110, 120 are electrically connected to one another by way of a connection medium. During operation, the contact elements 220, 221 of the pixelated light-emitting semiconductor chip 120 may be acted on electrically by the electronic semiconductor chip 110, such that the semiconductor chip 120 may be driven for light emission.

As is furthermore illustrated in FIG. 5, the electronic semiconductor chip 110 may comprise, with respect to one or more further light-emitting components or semiconductor chips 130 of the optoelectronic component structure 101, further front-side contact elements 212, 213, which may correspondingly constitute n- and p-contacts, respectively. As a result, contact elements of these components may be contacted by the electronic semiconductor chip 110 and may be acted on electrically by the semiconductor chip 110 during operation. The same correspondingly applies to the carrier 160, which may likewise comprise metallic contact elements 260, 261 at the front side lateral to the electronic semiconductor chip 110 in order to establish contact with contact elements of one or more further light-emitting components or semiconductor chips 130 of the optoelectronic component structure 101. The contact elements 260, 261 may also constitute n- and p-contacts, respectively. In this case, the contact elements 260, 261 of the carrier 160 are suitably electrically connected to the electronic semiconductor chip 110, as is indicated with the aid of dashed lines in FIG. 5, such that during operation, by way of the electronic semiconductor chip 110, corresponding electrical potentials may be applied to contact elements of the optoelectronic component structure 101 that are contacted by way of the contact elements 260, 261. The electrical connection between the contact elements 260, 261 of the carrier 160 and the electronic semiconductor chip 110 may be realized inter alia by way of metallic conductor structures of the carrier 160 (for example front-side conductor tracks 270 as shown in FIG. 11).

In the case of the optoelectronic module 100 in FIG. 5, the front-side contact elements 210, 211, 212, 213 of the electronic semiconductor chip 110 and contact elements 260, 261 of the carrier 160 that are used for contacting the optoelectronic component structure 101 lie in a horizontal plane, and therefore form a contacting plane. Components on the electronic semiconductor chip 110 may be electrically driven by way of the contact elements 210, 211, 212, 213 and components located partly or wholly next to the semiconductor chip 110 may be electrically driven by way of the contact elements 260, 261. Depending on the configuration of the optoelectronic module 100 and the optoelectronic component structure 101 thereof, different numbers of contact elements 210, 211, 212, 213, 215, 260, 261 may be provided, which may also include presence of for example only one or none of the contact elements 212, 213 on the electronic semiconductor chip 110 or presence of only one or none of the contact elements 260, 261 on the carrier 160.

As is illustrated in FIG. 5, the electronic semiconductor chip 110 furthermore comprises a plurality of switches 115, with the aid of which the operation of the optoelectronic component structure 101 for light emission may be controlled. The switches 115 may be realized in the form of transistors. With regard to the pixelated light-emitting semiconductor chip 120, the separate contact elements 211 of the electronic semiconductor chip 110 are electrically connected to a respective switch 115. In this way, it is possible, by selective switching of the switches 115, selectively to energize individual, a plurality or all of the light-emitting regions 125 and thus pixels 155 of the pixelated light-emitting semiconductor chip 120 (cf. FIG. 4), and thereby to drive same for light emission. As illustrated in FIG. 5, further contact elements 213, 261 of the electronic semiconductor chip 110 and carrier 160, respectively, may also be electrically connected to a respective switch 115 of the electronic semiconductor chip 110, such that the components or semiconductor chips 130 contacted thereby may be driven selectively for light emission in a corresponding manner by selective switching of the associated switches 115.

The electronic semiconductor chip 110 furthermore comprises further electrical or electronic circuit structures which are electrically connected to the switches 115 and (in part by way of the switches 115) to the contact elements 210, 211, 212, 213, 215, 260, 261 and by way of which abovementioned functions such as driving the switches 115, providing electrical potentials suitable for operation of the optoelectronic component structure 101, and data communication or processing of control signals communicated to the electronic semiconductor chip 110 may be performed. These circuit structures are schematically illustrated in combined form as IC logic 111 (integrated circuit) in FIG. 5.

The carrier 160 may comprise a semiconductor material such as silicon, for example, as carrier material or basic material. A configuration of the carrier 160 comprising a ceramic material such as silicon nitride, aluminum nitride or aluminum oxide, for example, is also possible. As a result, the carrier 160 may comprise a thermal expansion behavior corresponding to that of the electronic semiconductor chip 110 and the optoelectronic component structure 101. Occurrence of different thermal expansions and associated mechanical stresses with the possible consequence of damage to the optoelectronic module 100 may be avoided in this way. Furthermore, the carrier 160 is suitable for reliable heat dissipation.

The optoelectronic module 100 may be applied for example in a headlight of an adaptive lighting system (AFS or μAFS, micro-structured adaptive front-lighting system) of a motor vehicle. For such an application, the optoelectronic module 100 may be arranged in a projection or headlight module (not illustrated). In this case, for example, a light pattern with a high spatial resolution may be provided by the pixelated light-emitting semiconductor chip 120 at one location of an illumination region, for example in the center thereof, and light patterns with a lower spatial resolution may be provided by further light-emitting components or semiconductor chips 130 at another location of the illumination region, for example at the edge. Moreover, the semiconductor chip 120 may be employed for generating a low-beam light, and further light-emitting components or semiconductor chips 130 may be employed for realizing a high-beam light or travel direction indicator. In a departure from FIG. 5 and further figures showing a significant distance between the components of the optoelectronic component structure 101, the components may be positioned close to one another. A continuous illumination without visible boundaries between the components may be attained as a result.

The construction of the optoelectronic module 100 comprising the optoelectronic component structure 101, the electronic semiconductor chip 110 and the carrier 160 affords the possibility of a high configuration flexibility. Different configurations of the optoelectronic module 100 with a different light source geometry may be realized here with in each case the same electronic semiconductor chip 110, and by way of different configurations of the optoelectronic component structure 101 and optionally of the carrier 160. Since this approach does not involve complex changes in the electronic semiconductor chip 110, different configurations of the optoelectronic module 100 may be produced cost-effectively. Moreover, the electronic semiconductor chip 110 may comprise compact dimensions, which is likewise cost-effective.

With reference to the following figures, on the basis of FIG. 5, a more detailed description will be given of possible configurations or modifications of the optoelectronic module 100 in which the optoelectronic component structure 101 likewise comprises a pixelated light-emitting semiconductor chip 120 and one or more further components. Inter alia, the arrangement and contacting of the further components will be discussed here. Furthermore, in contrast to FIG. 5, in some instances simpler illustrations are employed in which details of the electronic semiconductor chip 110 such as the switches 115 thereof have been omitted. The same applies to the pixelated light-emitting semiconductor chip 120, for which in some instances only the separate contact elements 221 and, on the part of the electronic semiconductor chip 110, only the separate contact elements 211 are illustrated.

FIG. 6 shows a lateral sectional illustration of the optoelectronic module 100 in accordance with one configuration in which the optoelectronic component structure 101 comprises a light-emitting semiconductor chip 130 arranged next to the pixelated light-emitting semiconductor chip 120 on the carrier 160. In this case, the rear-side contact elements 230, 231 of the semiconductor chip 130 are electrically connected to opposite contact elements 260, 261 of the carrier 160 by way of a connection medium. As described above with regard to FIG. 5, there is an electrical connection between the contact elements 260, 261 of the carrier 160 and the electronic semiconductor chip 110, such that the light-emitting semiconductor chip 130 may be electrically supplied by the electronic semiconductor chip 110 and thereby driven for light emission. In this case, the light emission from the semiconductor chip 130 occurs in a region lateral to the electronic semiconductor chip 110.

Referring to FIG. 6, it is possible for the optoelectronic component structure 101 to comprise a plurality of, for example three, light-emitting semiconductor chips 130 mounted next to one another on the carrier substrate 160, as is illustrated in the front-side plan view illustration in FIG. 10. FIG. 10 furthermore shows the above-explained configuration of the electronic semiconductor chip 110 with a plurality of contact elements 215 arranged next to one another. Furthermore, the rear-side contact elements 230, 231 of the light-emitting semiconductor chips 130 and the rear-side contact structure of the pixelated light-emitting semiconductor chip 120 with the continuous contact element 220 and the separate contact elements 221 arranged in cutouts of the contact element 220 are indicated.

According to FIG. 6, a contacting of the contact elements 230, 231 of the three light-emitting semiconductor chips 130 is established by way of in each case two contact elements 260, 261 of the carrier 160. The contact elements 260, 261 may be electrically connected to the electronic semiconductor chip 110 inter alia by way of conductor structures of the carrier 160. For further illustration, FIG. 11 shows a plan view illustration corresponding to FIG. 10, with an exemplary configuration suitable for this purpose, according to which front-side conductor tracks 270 of the carrier 260 are used. The three light-emitting semiconductor chips 130 of the component structure 101 are indicated here only by dashed lines. Moreover, the pixelated light-emitting semiconductor chip 120 has been omitted, such that the contact structure of the electronic semiconductor chip 110 that is used for contacting the semiconductor chip 120, i.e. the continuous contact element 210 and the separate contact elements 211 arranged in cutouts of the contact element 210, is visible.

As is illustrated in FIG. 11, three contact elements 260 of the carrier 160 may be electrically connected to a contact element 215 of the electronic semiconductor chip 110 by virtue of the carrier 160 comprising short conductor tracks 270 connecting the contact elements 260, and a longer conductor track 270 guided to the contact element 215. At this location, the contact element 215 and the conductor track 270 extending to the contact element 215 are connected to one another by way of an electrically conductive connection structure 181. The connection structure 181 may be for example a bond wire or a metallic connection layer. With regard to three other contact elements 261 of the carrier 160, a contact element 261 is electrically connected to a further contact element 215 of the electronic semiconductor chip 110 by way of a conductor track 270 and a connection structure 181. For the other two contact elements 261, a joint electrical connection to a further contact element 215 of the semiconductor chip 110 is established by way of conductor tracks 270 and a connection structure 181. In the configuration shown in FIG. 11, a common electrical potential may be applied to the contact elements 260 by the electronic semiconductor chip 110 and by way of the respective connections between the contact elements 260, 261 of the carrier 160 and the corresponding contact elements 215 of the electronic semiconductor chip 110, and a further electrical potential may in each case be applied to the separately connected contact element 261 and to the two jointly connected contact elements 261. As a result, of the three light-emitting semiconductor chips 130, one semiconductor chip 130 may be driven separately and two semiconductor chips 130 may be driven jointly by the electronic semiconductor chip 110 for light emission purposes.

FIG. 11 supplementarily indicates a further configuration such as may be considered in regard to the electronic semiconductor chip 110 being contacted externally. In this case, the carrier 160 comprises contact elements 265 and front-side conductor tracks 271 which are electrically connected thereto and guided to contact elements 215 of the electronic semiconductor chip 110 and which are electrically connected to the contact elements 215 by way of connection structures 181. In FIG. 11, this connection is illustrated only for one contact element 215 and one contact element 265, and is indicated only by dashed lines for further contact elements 215, 265. In this configuration, the electrical supply of the electronic semiconductor chip 110 and data communication with the semiconductor chip 110 may be realized by way of the contact elements 265 of the carrier 160.

Referring to FIGS. 6, 10 and 11, one possible modification consists in configuring the optoelectronic module 100 in such a way that the light-emitting semiconductor chip(s) 130 mounted on the carrier 160 partly overlap(s) the electronic semiconductor chip 110, such that a light emission from the semiconductor chips 130 may also be caused in the region of the electronic semiconductor chip 110. Referring to FIG. 11, modifications consist in correspondingly configuring conductor tracks 270 for all contact elements 261 of the carrier 160 so as to establish a joint electrical connection to one contact element 215 or alternatively separate electrical connections to contact elements 215 of the electronic semiconductor chip 110, such that the semiconductor chips 130 may be driven by the semiconductor chip 110 jointly or separately for light emission purposes (neither case being depicted).

The carrier 160 of the optoelectronic module 100 may be embodied in one piece, and, as described above, may comprise a depression 161 for receiving the electronic semiconductor chip 110. A multipartite configuration of the carrier 160 is also possible. For illustration, FIG. 7 shows a further configuration of the optoelectronic module 100 in a lateral sectional view, this further configuration substantially corresponding to FIG. 6. In this case, the carrier 160 comprises a plate-type base part 162 and a further carrier part 163. The electronic semiconductor chip 110 is arranged on the base part 162. The further carrier part 163 comprises a frame-type shape enclosing a cutout, and is arranged on the base part 162 laterally next to the electronic semiconductor chip 110, such that the semiconductor chip 110 is laterally enclosed by the carrier part 163. The further carrier part 163 comprises a thickness such that a front side of the electronic semiconductor chip 110 terminates flush or substantially flush with a front side of the carrier part 163.

In the case of a multipartite configuration of the carrier 160, details described above and also below may be applied in a corresponding manner. In this regard, both carrier parts 162, 163 or at least the carrier part 163 may be formed from silicon or a ceramic material. If the carrier 160 comprises contact elements 260, 261, as is shown in FIG. 7, the contact elements 260, 261 may be arranged on the carrier part 163. Furthermore, the contact elements 260, 261 may be suitably electrically connected to the electronic semiconductor chip 110, which may be realized inter alia by front-side conductor tracks arranged on the carrier part 163, for example in accordance with FIG. 11.

Moreover, further modifications are conceivable for the carrier 160. By way of example, the further carrier part 163 may not comprise a shape enclosing the electronic semiconductor chip 110, but rather a different shape, for example partly or not enclosing the semiconductor chip 110, or else a plate-type shape. Furthermore, configurations comprising a larger number of carrier parts arranged one over another are conceivable. It is also possible to realize an electrical connection of front-side contact elements 260, 261 of the carrier 160 by way of other conductor structures of the carrier 160 such as, for example, vias and conductor or conductor track structures led within the carrier 160 (the drawings do not depict this). Multipartite designs of the carrier 160 may be employed in a corresponding manner for configurations of the optoelectronic module 100 explained hereinafter.

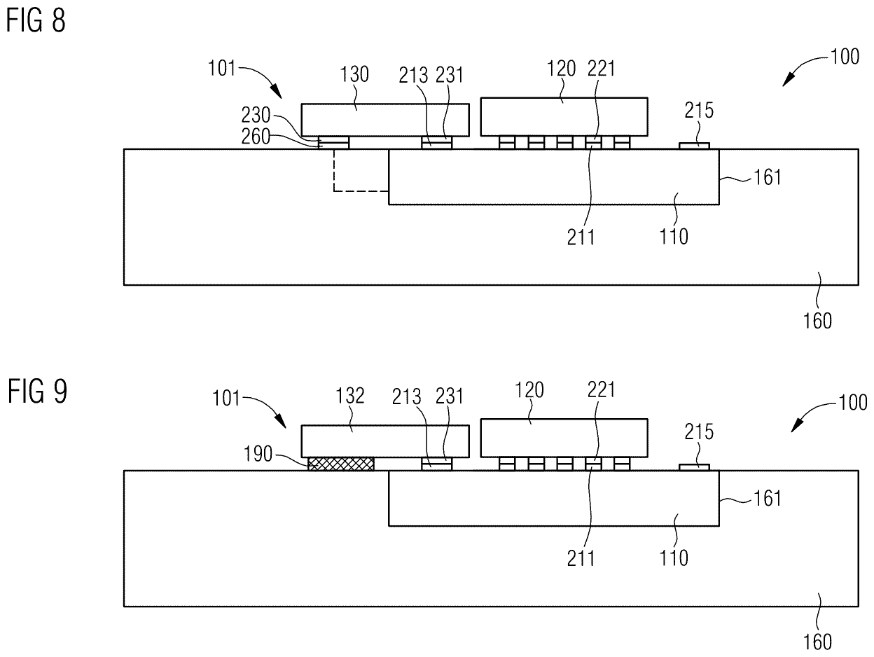

FIG. 8 shows a lateral sectional illustration of the optoelectronic module 100 in accordance with one configuration in which the optoelectronic component structure 101 comprises a light-emitting semiconductor chip 130 arranged next to the pixelated light-emitting semiconductor chip 120 on the electronic semiconductor chip 110 and on the carrier 160. In this case, the rear-side contact element 231 of the semiconductor chip 130 is electrically connected to an opposite contact element 213 of the electronic semiconductor chip 110, and the rear-side contact element 230 of the semiconductor chip 130 is electrically connected to an opposite contact element 260 of the carrier 160. The electrical connection is established by way of a connection medium in each case. As described above, there is an electrical connection between the contact element 260 of the carrier 160 and the electronic semiconductor chip 110. In this way, the light-emitting semiconductor chip 130 may be electrically supplied by the semiconductor chip 110 by way of the contact element 213 thereof and by way of the contact element 260 of the carrier 160 and may thereby be driven for light emission purposes. In this configuration, the electronic semiconductor chip 110 and also the carrier 160 lateral to the semiconductor chip 110 are covered in a region by the semiconductor chip 130 present in the form of a contact bridge, such that a light emission from the semiconductor chip 130 may be effected in the region of the electronic semiconductor chip 110 and also lateral to the semiconductor chip 110.

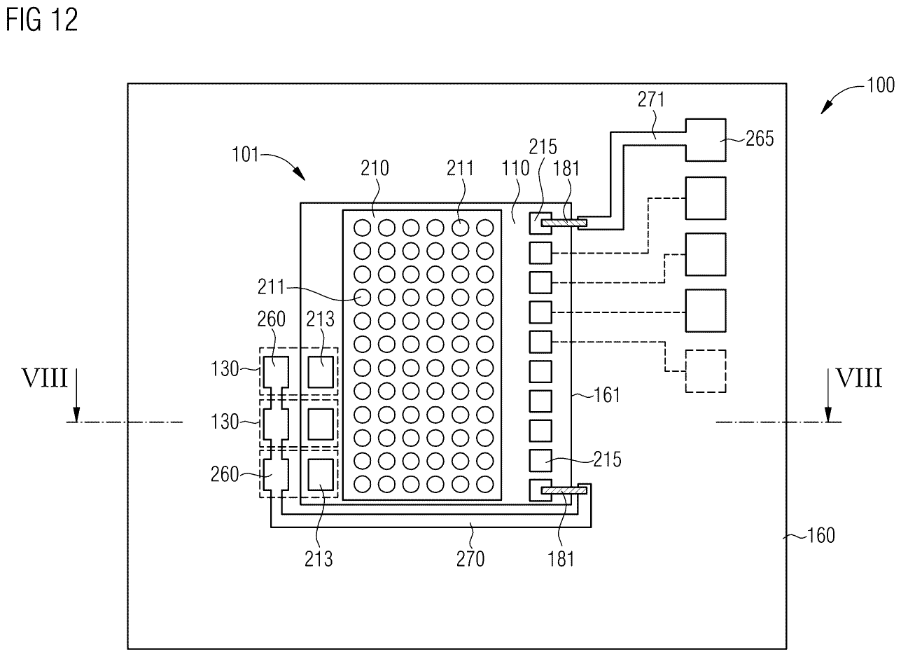

With regard to FIG. 8, it is likewise possible for the optoelectronic component structure 101 to comprise a plurality of, for example three, semiconductor chips 130 mounted next to one another on the electronic semiconductor chip 110 and the carrier 160, as is illustrated in the plan view illustration in FIG. 12. In this case, the three semiconductor chips 130 are indicated by dashed lines, and the pixelated light-emitting semiconductor chip 120 has been omitted. In accordance with FIG. 8, the three semiconductor chips 130 are contacted in each case by way of a contact element 260 of the carrier 160 and a contact element 213 of the electronic semiconductor chip 110. As is furthermore shown in FIG. 12, the three contact elements 260 of the carrier 160 may be electrically connected to a contact element 215 of the electronic semiconductor chip 110 by way of short conductor tracks 270 connecting the contact elements 260, and a longer conductor track 270 guided to the contact element 215, and also a connection structure 181. In this way, a common electrical potential may be applied to the contact elements 260 by way of the electronic semiconductor chip 110 and the established connection between the contact element 215 thereof and the contact elements 260 of the carrier 160. Furthermore, the semiconductor chip 110 may apply a further electrical potential at each of its contact elements 213. As a result, the three light-emitting semiconductor chips 130 may be driven in each case for light emission purposes.

For the optoelectronic module 100, a configuration is possible in which the optoelectronic component structure 101 comprises a light-emitting component which is mounted next to the pixelated light-emitting semiconductor chip 120 on the electronic semiconductor chip 110 and is contacted by the latter. This is indicated for example in FIG. 5 with the aid of a semiconductor chip 130 indicated by dashed lines and located next to the semiconductor chip 120. In this case, the relevant semiconductor chip 130 may be contacted by way of contact elements 212, 213 of the electronic semiconductor chip 110 and in this respect may be electrically driven by the semiconductor chip 110.

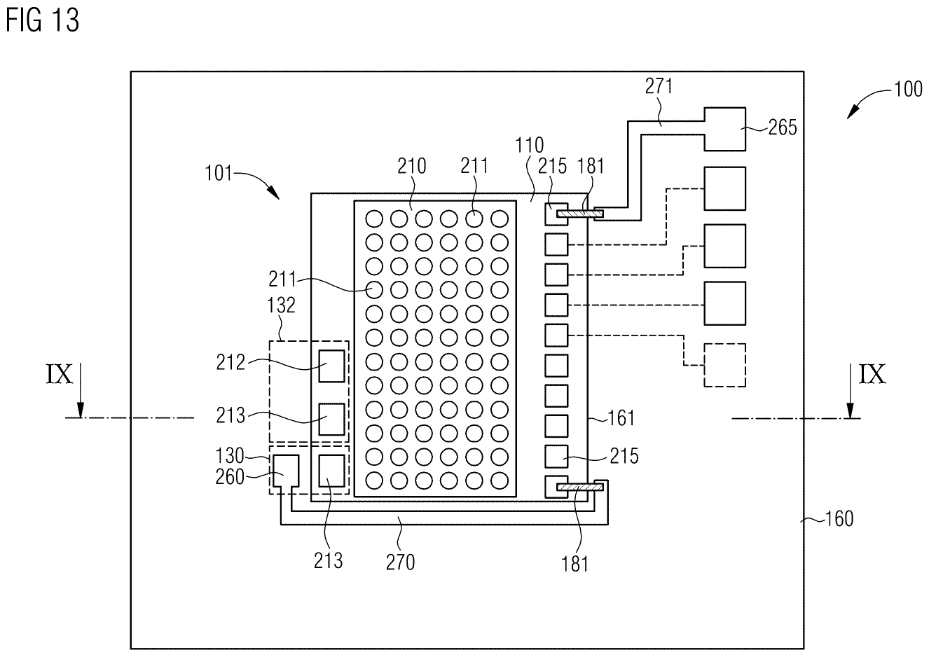

In one possible development, such a light-emitting component may additionally project beyond the electronic semiconductor chip 110 and also cover the carrier 160 in a region lateral to the semiconductor chip 110, such that a light emission may also be caused lateral to the semiconductor chip 110. For illustration purposes, FIGS. 9 and 13 depict a configuration realized to that effect for the optoelectronic module 100 in a lateral sectional view and a plan view illustration. The optoelectronic component structure 101 here comprises two light-emitting semiconductor chips 130, 132 with in each case two rear-side contact elements 230, 231 arranged next to the pixelated light-emitting semiconductor chip 120 (omitted in FIG. 13). The semiconductor chip 132 comprises a horizontal configuration corresponding to the semiconductor chip 130, and differs from the semiconductor chip 130 by virtue of a different plan view shape with larger lateral dimensions and a different arrangement of the contact elements 230, 231. The rear-side contact element 231 of the semiconductor chip 132 is electrically connected to an opposite contact element 213 of the electronic semiconductor chip 110 (cf. FIGS. 9 and 13), and the further rear-side contact element 230 (not shown) of the semiconductor chip 132 is electrically connected to a further opposite contact element 212 of the semiconductor chip 110 (cf. FIG. 13). The connection is established by way of a connection medium in each case. In the case of the other semiconductor chip 130, an arrangement and contacting, here by way of a contact element 260 of the carrier 160 and a further contact element 213 of the electronic semiconductor chip 110, are present such as have been explained above with reference to FIG. 8. In this case, the contact element 260 of the carrier 160 is connected to a contact element 215 of the electronic semiconductor chip 110 by way of a conductor track 270 and a connection structure 181. During operation, corresponding electrical potentials may be applied to the contact elements 212, 213, 260 by the semiconductor chip 110 in order to drive the semiconductor chips 130, 132 for light emission.

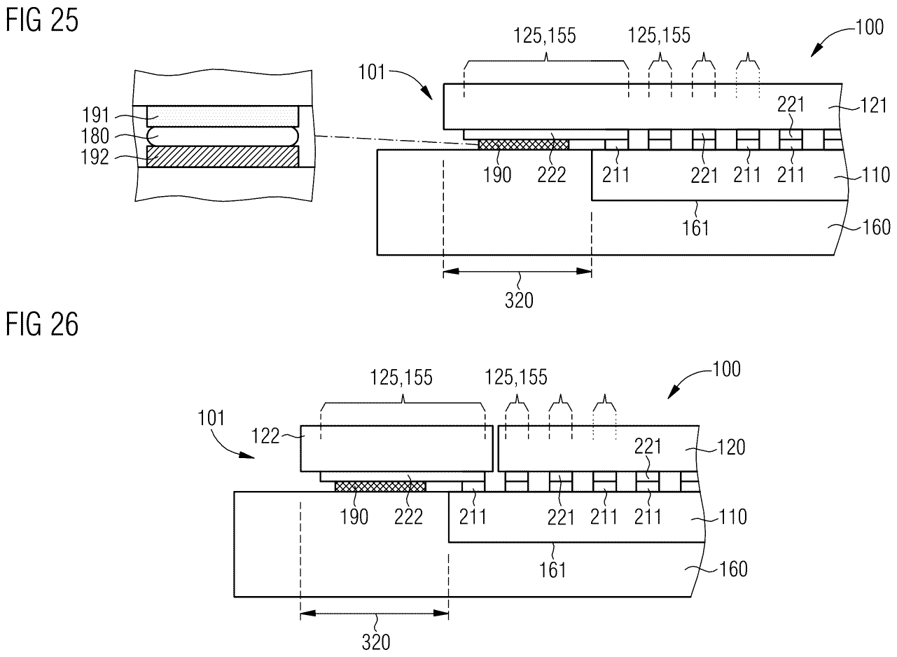

As is illustrated in FIG. 9, the light-emitting semiconductor chip 132 projecting beyond the electronic semiconductor chip 110 may additionally be mounted on the carrier 160. In this case, the semiconductor chip 132 and the carrier 160 are purely thermally conductively connected to one another, as is illustrated with the aid of a layer-type thermal connection structure 190 in FIG. 9. By way of the thermal connection structure 190, heat dissipation during operation of the semiconductor chip 132 may additionally be made possible by way of the carrier 160. The thermal connection structure 190 may comprise inter alia a connection medium 180 in the form of a solder. Furthermore, a configuration such as is explained further below in association with FIG. 25 may be employed for the connection structure 190. If a multipartite configuration of the carrier 160 corresponding to FIG. 7 is present, a connection to the further carrier part 163 may be established by way of the connection structure 190.

For the optoelectronic module 100, designs may be considered in which the optoelectronic component structure 101 comprises one or more light-emitting semiconductor chips with contact elements arranged at both sides, as has been explained with reference to FIG. 1. For illustration purposes, FIGS. 14 and 15 depict a configuration realized to that effect for the optoelectronic module 100 in a lateral sectional view and a plan view illustration. In this case, the optoelectronic component structure 101 comprises a plurality of light-emitting semiconductor chips 130, 140, 141, 142 located next to the pixelated light-emitting semiconductor chip 120. In the case of the semiconductor chips 130 comprising only rear-side contact elements (not shown) contacted by the electronic semiconductor chip 110 and the carrier 160, a configuration corresponding to FIG. 8 may be present.

The other light-emitting semiconductor chips 140, 141, 142 are realized in accordance with the vertical configuration explained with reference to FIG. 1, and each comprise a rear-side contact element 230 and a front-side contact element 231 as shown in FIG. 14. The semiconductor chips 140, 141, 142 differ from one another by virtue of different plan view shapes and lateral dimensions. The rear-side contact elements 230 of the semiconductor chips 140, 141, 142 are each electrically connected to opposite contact elements 213 of the electronic semiconductor chip 110 by way of a connection medium. Furthermore, the semiconductor chips 140, 141, 142 project beyond the electronic semiconductor chip 110 and thereby cover the carrier 160 in a region lateral to the semiconductor chip 110, such that during operation the semiconductor chips 140, 141, 142 may cause a light emission in the region of the electronic semiconductor chip 110 and lateral thereto. With regard to the carrier 160, the semiconductor chips 140, 141, 142 may additionally be thermally conductively connected to the carrier 160 and thereby mounted on the carrier 160. FIG. 14 illustrates this configuration for a semiconductor chip 140 connected to the carrier 160 by way of a layer-type thermal connection structure 190. Such a configuration may also be realized for the other semiconductor chips 141, 142.

As is furthermore illustrated in FIG. 14, the front-side contact elements 231 of the light-emitting semiconductor chips 140, 141, 142 are jointly electrically connected to a contact element 260 of the carrier 160 by virtue of the optoelectronic module 100 comprising a planar contact layer 187 connected to the contact elements 231, 260. The contact layer 187, not depicted in FIG. 15, may at least partly cover the contact element 260 and the semiconductor chips 140, 141, 142. The contact layer 187, also referred to as PI contact (planar interconnect), may be transparent, and for this purpose may be realized in the form of an ITO layer (indium tin oxide). The contact element 260 of the carrier 160, which contact element may comprise an elongate shape in plan view, is furthermore electrically connected to the electronic semiconductor chip 110 in a suitable manner, such that the front-side contact elements 231 of the semiconductor chips 140, 141, 142 may be jointly electrically acted on by the semiconductor chip 110 by way of the contact element 260 and the contact layer 187. The connection may be established by way of a conductor track structure 270 and a connection structure 181 in accordance with the above description, such that the contact element 260 of the carrier 160 may be electrically connected to a contact element 215 of the semiconductor chip 110 (not illustrated). During operation, corresponding electrical potentials may be applied to the contact elements 213, 260 by the electronic semiconductor chip 110 in order to drive the semiconductor chips 130, 140, 141, 142 in each case for light emission.

A contacting of a front-side contact element 231 of a light-emitting semiconductor chip configured in a vertical design may be realized not only by the use of a contact layer 187, but also for example in the form of a wire contacting. For illustration, FIG. 16 shows a further configuration of the optoelectronic module 100 with a light-emitting semiconductor chip 140 mounted on the electronic semiconductor chip 110 and the carrier 160. An electrical connection between the front-side contact element 231 of the semiconductor chip 140 and a contact element 260 of the carrier 160 is established by way of a bond wire 185.

In the case of the optoelectronic module 100, provision is made for a front side of the electronic semiconductor chip 100 to terminate flush or substantially flush with a front side of the respectively used carrier 160 that is located laterally next to the semiconductor chip 110. It is possible for the semiconductor chip 110 to project relative to the carrier 160 or for the carrier 160 to project relative to the semiconductor chip 110 and, in this respect, as is shown in a lateral sectional view in FIGS. 17 and 18, for there to be a level difference 330 between these components 110, 160. The level difference 330 may be in the micrometers range or amount to a maximum of 1 μm. As a result, the optoelectronic component structure 101 may be reliably mounted on the electronic semiconductor chip 110 and the carrier 160 without for example the risk of semiconductor chips breaking.

The carrier 160 of the optoelectronic module 100 may comprise a carrier material or basic material which is electrically nonconductive or insulating. This is the case for example with the use of a ceramic material such as silicon nitride, aluminum nitrite or aluminum oxide, as mentioned above. In such a configuration, contact elements 260, 261 of the carrier 160 may be electrically connected to the electronic semiconductor chip 110 inter alia by way of conductor structures of the carrier 160 such as conductor tracks 270 (cf. FIG. 11, for example).

In one modification, the carrier 160 may be configured to be electrically conductive at least in the region of its front side and, for this purpose, may comprise an electrically conductive carrier material, for example a doped semiconductor material such as doped silicon. In such a configuration, it is possible to realize, for one or more contact elements of the carrier 160, an electrical connection to the electronic semiconductor chip 110 inter alia by way of the electrically conductive carrier material itself, rather than by way of conductor or conductor track structures. Referring to FIGS. 12 and 13, this may be considered for the contact elements 260, for example. In this case, the conductor tracks 270 may be omitted, and the electronic semiconductor chip 110 or a contact element 215 of the semiconductor chip 110 may be electrically connected to the carrier 160 or to the electrically conductive carrier material, such that a common electrical potential may be applied to the contact elements 260 by the semiconductor chip 110. For the connection between the carrier 160 and the semiconductor chip 110, the carrier 160 may comprise a further contact element which may be connected to the contact element 215 of the semiconductor chip 110 by way of a connection structure 181. The common electrical potential may be an n- or p-potential, and a ground or grounding potential. It is furthermore conceivable for no electrical connection to the electronic semiconductor chip 110 to be provided for one or more contact elements of the carrier 160 such as the contact elements 260 shown in FIGS. 12 and 13. Instead, a ground potential may be applied to these contact elements 260 or to the carrier 160 externally. For this purpose, the carrier 160 may comprise a further contact element used for external contacting (not depicted in the drawings).

FIG. 19 shows a perspective illustration of an optoelectronic module 100 in accordance with a further configuration, which module may be used in a headlight of a motor vehicle. The optoelectronic component structure 101 of the module 100 comprises a pixelated light-emitting semiconductor chip 120 arranged on the electronic semiconductor chip 110. In FIG. 19, the semiconductor chip 120 is illustrated as see-through, and so the rear-side contact structure of the semiconductor chip 120 comprising the continuous contact element 220 and the separate contact elements 221 arranged in cutouts of the contact element 220 is shown. The semiconductor chip 120 is mounted on the electronic semiconductor chip 110 in a manner corresponding to FIG. 5. The component structure 101 furthermore comprises a plurality of light-emitting semiconductor chips 130, 131 which are arranged next to the semiconductor chip 120 on the electronic semiconductor chip 110 and the carrier 160 and are contacted by the semiconductor chip 110 and the carrier 160. The semiconductor chips 130, 131 comprise rear-side contact elements 230, 231 (not shown), and are mounted on the semiconductor chip 110 and the carrier 160 in a manner corresponding to FIG. 8. The semiconductor chips 130, 131 cover the carrier 160 to a greater extent than the electronic semiconductor chip 110. The semiconductor chips 120, 130, 131 are positioned relatively close to one another, with the result that a continuous illumination without visible boundaries is possible. The semiconductor chip 131 differs from the other semiconductor chips 130 by virtue of a different plan view shape with larger lateral dimensions. In the case of the optoelectronic module 100 in FIG. 19, a light emission may be caused in the region of the electronic semiconductor chip 110 by way of the pixelated light-emitting semiconductor chip 120, and in the region of the semiconductor chip 110 and in a region lateral thereto by way of the light-emitting semiconductor chips 130, 131. It is possible to realize a low-beam light by way of the semiconductor chip 120, a high-beam light by way of the semiconductor chips 130, and a travel direction indicator by way of the semiconductor chip 131.

FIG. 20 shows as an excerpt a further perspective illustration of the optoelectronic module 100 from FIG. 19 without the semiconductor chips 120, 130. The illustration here shows the contact structure of the electronic semiconductor chip 110 comprising the continuous contact element 210 and the separate contact elements 211 arranged in cutouts thereof, this contact structure being coordinated with the pixelated light-emitting semiconductor chip 120. The illustration furthermore shows the contact elements 213 of the semiconductor chip 110 and contact elements 260 of the carrier 160 that are provided for the contacting of the semiconductor chips 130. Such a pair of contact elements 213, 260 is likewise present for the contacting of the semiconductor chip 131. In line with the description above, the contact elements 260 of the carrier 160 may be electrically connected to the electronic semiconductor chip 110 in a suitable manner (not illustrated). Furthermore, the contact element 210 and the contact elements 260 may be n-contacts, and the contact elements 211, 213 may be p-contacts.

In accordance with FIG. 20, the contact elements 260 of the carrier 160 comprise larger lateral dimensions than the contact elements 213 of the electronic semiconductor chip 110. The rear-side contact elements 230, 231 of the semiconductor chips 130, 131 that are contacted thereby comprise lateral dimensions of different sizes corresponding thereto (not illustrated). In this way, reliable heat dissipation is possible by way of the carrier 160 during operation of the light-emitting semiconductor chips 130, 131. The semiconductor chips 130, 131 may therefore be powerful light-emitting diode chips, for example.

In the case of the optoelectronic module 100 in FIG. 19 (and also configurations from previous figures), a light emission from the pixelated light-emitting semiconductor chip 120 may be caused only in the region of the electronic semiconductor chip 110. In a departure from this, a configuration going beyond the electronic semiconductor chip 110 may be considered in order to cause a light emission, in accordance with the light-emitting semiconductor chips 130, 131, also in a region lateral to the semiconductor chip 110.

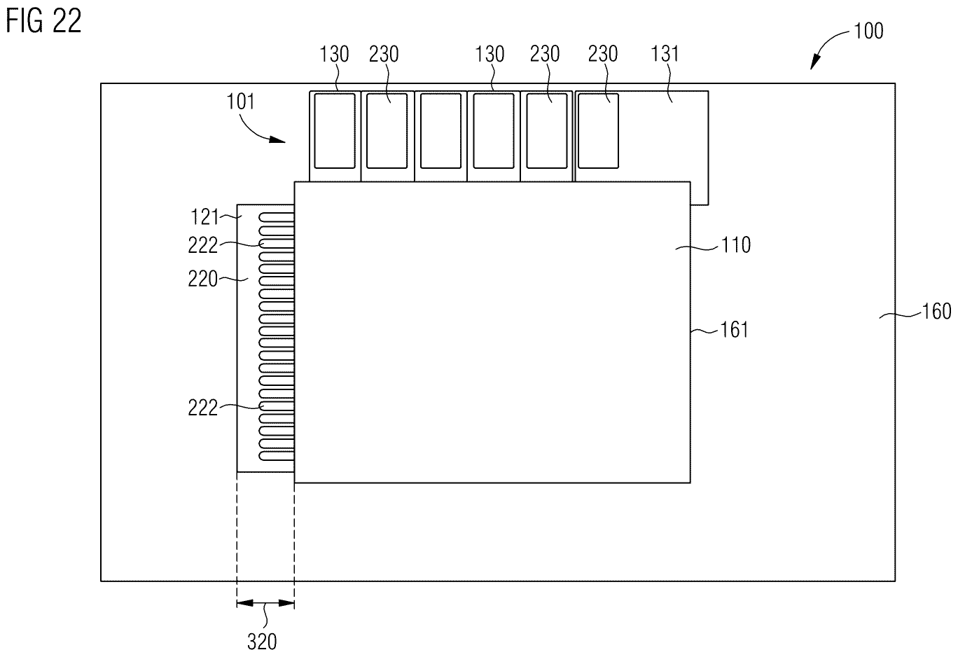

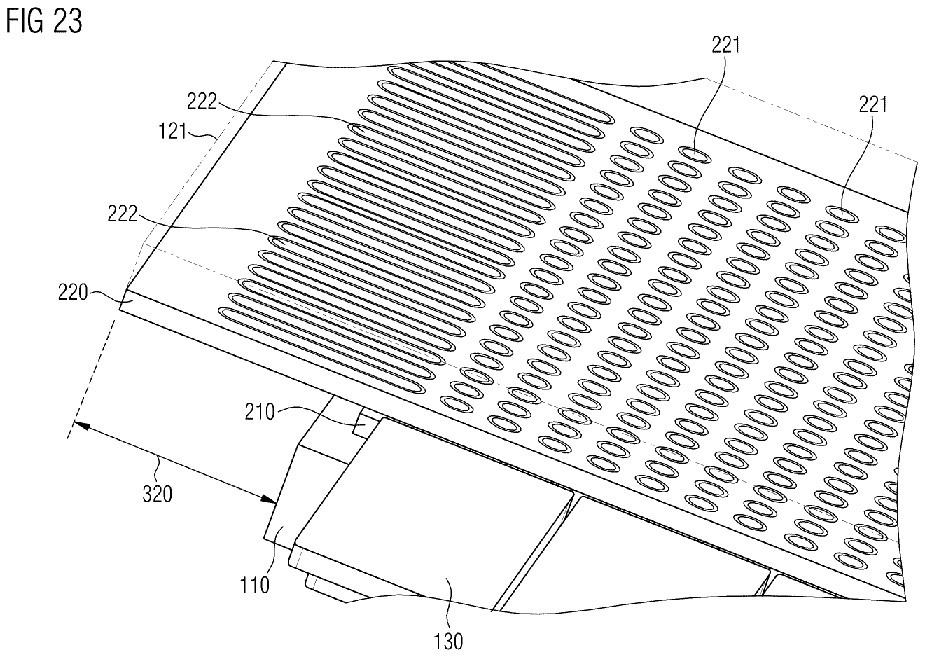

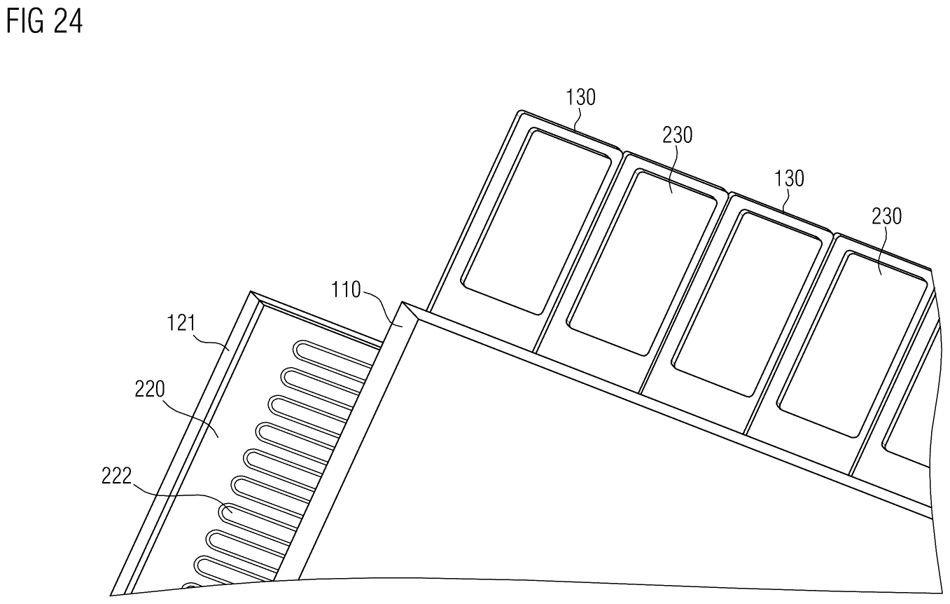

For illustration, FIG. 21 shows a perspective illustration of an optoelectronic module 100 which is configured to that effect and which represents a development of the module 100 from FIG. 19 and substantially corresponds thereto. The optoelectronic module 100 in FIG. 21 comprises, instead of the pixelated light-emitting semiconductor chip 120, a pixelated light-emitting semiconductor chip 121 which projects laterally beyond the electronic semiconductor chip 110 and thereby covers the carrier 160 in an overlap region 320 lateral to the semiconductor chip 110. This configuration also becomes clear with the aid of the rear-side illustration in FIG. 22, the perspective excerpt illustrations in FIGS. 23 and 24 and the lateral sectional illustration in FIG. 25. In the rear view in FIG. 22, the carrier 160 is see-through and its outer contour is illustrated, such that rear-side contact elements 230 of the semiconductor chips 130, 131 and part of a rear-side contact structure of the semiconductor chip 121 are depicted. In FIGS. 21 and 23, the pixelated light-emitting semiconductor chip 121 is illustrated as see-through, such that the rear-side contact structure of the semiconductor chip 121 is shown. In FIGS. 23 and 24, the carrier 160 has been omitted.

The rear-side contact structure of the pixelated light-emitting semiconductor chip 121 substantially corresponds to the rear-side contact structure of the pixelated light-emitting semiconductor chip 120 explained previously, that is to say that the semiconductor chip 121 comprises a continuous contact element 220 with cutouts and separate contact elements 221 arranged within the cutouts. The configuration with the contact elements 221 is present in the region of the electronic semiconductor chip 110. With regard to the overlap region 320, the semiconductor chip 121 comprises further separate contact elements 222 in an edge region, which contact elements are likewise arranged in cutouts provided here in the continuous contact element 220. The contact elements 222 and the associated cutouts of the contact element 220 comprises an elongate or oval shape, and comprise larger dimensions than the other circular separate contact elements 221 and associated cutouts of the contact element 220. This becomes clear with the aid of FIGS. 21 and 23, which depict the rear-side contact structure of the semiconductor chip 121. In this case, the circular separate contact elements 221 are located only in the region of the electronic semiconductor chip 110. By contrast, the elongate separate contact elements 222 likewise located in the region of the semiconductor chip 110, and also the continuous contact element 220 of the semiconductor chip 121, additionally project laterally beyond the electronic semiconductor chip 110 and are thus also present in the overlap region 320. In this way, it is possible to act electrically on the semiconductor layer sequence of the semiconductor chip 121 by way of the contact elements 220, 222 thereof in the overlap region 320 as well. The contact elements 222 may constitute p-contacts in a manner corresponding to the contact elements 221.

Like the pixelated light-emitting semiconductor chip 120 explained previously, the pixelated light-emitting semiconductor chip 121 comprises light-emitting regions 125 and thus pixels 155 (cf. FIG. 3). In a manner corresponding to the elongate contact elements 222, the light-emitting regions 125 and thus pixels 155 associated with the contact elements 222 comprise an elongate shape, and therefore comprise larger dimensions than the light-emitting regions 125 and pixels 155 associated with the other contact elements 221. Consequently, the semiconductor chip 121, as is indicated in FIG. 25, comprises light-emitting regions 125 and pixels 155 comprising different lateral dimensions, i.e. light-emitting regions 125 and pixels 155 comprising relatively small dimensions which are present in the region of the electronic semiconductor chip 110 and, in a manner responding to the elongate contact elements 222, elongate light-emitting regions 125 and pixels 155 comprising larger lateral dimensions which are present in an edge region and which project beyond the electronic semiconductor chip 110. By way of the smaller pixels 155, a light emission may be caused in the region of the electronic semiconductor chip 110, and by way of the elongate pixels 155, a light emission may be caused in an edge region of the semiconductor chip 110 and in a region lateral to the semiconductor chip 110 or in the overlap region 320.

The electrical contacting of the pixelated light-emitting semiconductor chip 121 is established by way of the electronic semiconductor chip 110 in a manner corresponding to the pixelated light-emitting semiconductor chip 120 explained previously, by virtue of the continuous contact elements 210, 220 and the separate contact elements 211, 221, 222 of the two semiconductor chips 110, 121 being electrically connected to one another by way of a connection medium. In this case, the separate elongate contact elements 222 of the semiconductor chip 121 are electrically connected to opposite separate contact elements 211 of the electronic semiconductor chip 110 that are arranged at the edge of the semiconductor chip 110, as becomes clear with the aid of FIG. 25. The other separate contact elements 221 of the semiconductor chip 121 are electrically connected to further opposite separate contact elements 211 of the semiconductor chip 110. In FIG. 25, in line with previous sectional illustrations, the continuous contact elements 210, 220 of the two semiconductor chips 110, 121 have been omitted for reasons of clarity. In this case, the continuous contact element 220 of the semiconductor chip 121 projects laterally beyond the electronic semiconductor chip 110 and the continuous contact element 210 thereof (cf. FIG. 23).

As is illustrated in FIG. 25, the pixelated light-emitting semiconductor chip 121 projecting beyond the electronic semiconductor chip 110, in the overlap region 320, may additionally be mounted on the carrier 160 and for this purpose may be only thermally conductively connected to the carrier 160 by way of a layer-type thermal connection structure 190. In this way, heat dissipation during operation of the semiconductor chip 121 may be made possible at this location by way of the carrier 160. As is shown in the enlarged excerpt in FIG. 25, the connection structure 190 may comprise a connection medium 180, for example a solder. In order to prevent an undesired electrical connection or occurrence of a short circuit from occurring on account of the connection medium 180, the semiconductor chip 121 may comprise a rear-side insulation layer 191, for example in the form of an oxide or nitride layer, in the region of the thermal link. Furthermore, the carrier 160 may comprise a metallic connection element 192, which may be connected to the semiconductor chip 121 or the insulation layer 191 by way of the connection medium 180. If a multipartite configuration of the carrier 160 corresponding to FIG. 7 is present, a connection to the further carrier part 163 may be established by way of the connection structure 190.

For the optoelectronic module 100, a configuration is conceivable in which the optoelectronic component structure 101 comprises a plurality of pixelated light-emitting semiconductor chips arranged next to one another. These chips may be arranged only on the electronic semiconductor chip 110 (not illustrated). A further possible configuration, representing a modification of the design explained with reference to FIGS. 21 to 25, is depicted in a lateral sectional illustration in FIG. 26. In this case, the component structure 101 comprises a pixelated light-emitting semiconductor chip 120 arranged on the electronic semiconductor chip 110, and, laterally with respect thereto, a further pixelated light-emitting semiconductor chip 122, which is mounted on the semiconductor chip 110 and on the carrier 160 and which projects laterally beyond the electronic semiconductor chip 110 and thereby covers the carrier 160 in an overlap region 320 lateral to the semiconductor chip 110. The two semiconductor chips 120, 122 may be interpreted as a multipartite configuration of the pixelated semiconductor chip 121 explained previously, as becomes clear from a comparison of FIGS. 25 and 26.

In this case, the pixelated light-emitting semiconductor chip 122 projecting beyond the electronic semiconductor chip 110 comprises the above-described configuration realized for the semiconductor chip 121 with regard to the overlap region 320, i.e. separate elongate contact elements 222 and associated elongate light-emitting regions 125 and pixels 155. The other semiconductor chip 120 comprises separate contact elements 221 and pixels 155, the dimensions of which are smaller than those of the contact elements 222 and pixels 155 of the semiconductor chip 122. The projecting semiconductor chip 122 furthermore comprises, in a manner corresponding to the semiconductor chip 120, a (not illustrated) continuous contact element 220 comprising cutouts with the separate elongate contact elements 222 arranged therein. The separate contact elements 222 of the semiconductor chip 122 are electrically connected to opposite separate contact elements 211 of the electronic semiconductor chip 110 that are arranged at the edge. The continuous contact element 220 of the projecting semiconductor chip 122 may be electrically connected to one or more contact elements of the electronic semiconductor chip 110 (not illustrated). The pixelated light-emitting semiconductor chip 122 is additionally mounted on the carrier 160 and thermally conductively connected thereto by way of a thermal connection structure 190. The other pixelated light-emitting semiconductor chip 120 is mounted on the electronic semiconductor chip 110 in a manner corresponding to FIG. 5. During operation, by way of the semiconductor chip 120, a light emission may be caused in the region of the electronic semiconductor chip 110, and by way of the semiconductor chip 122, a light emission may be caused in an edge region of the semiconductor chip 110 and lateral to the semiconductor chip 110 or in the overlap region 320.

In accordance with the configurations of the optoelectronic module 100 shown in FIG. 5 and subsequent figures, the electronic semiconductor chip 110 comprises front-side contact elements. A configuration in which the semiconductor chip 110 comprises contact elements at a front side and an opposite rear side is also possible. In this case, front-side contact elements may be used for controlling operation of the optoelectronic component structure 101, as has been explained above, and rear-side contact elements may be employed in order to supply the semiconductor chip 110 with electrical energy and to carry out data communication with the semiconductor chip 110. For this purpose, rear-side contact elements of the semiconductor chip 110 may be electrically connected to contact elements and conductor structures of the carrier 160. It is also possible to use rear-side contact elements of the semiconductor chip 110 for controlling operation of an optoelectronic component of the component structure 101.

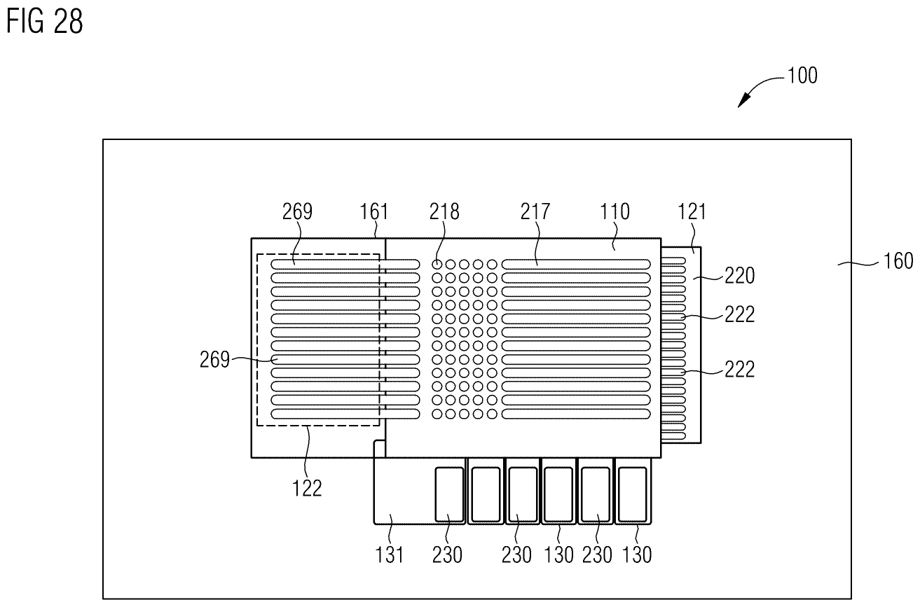

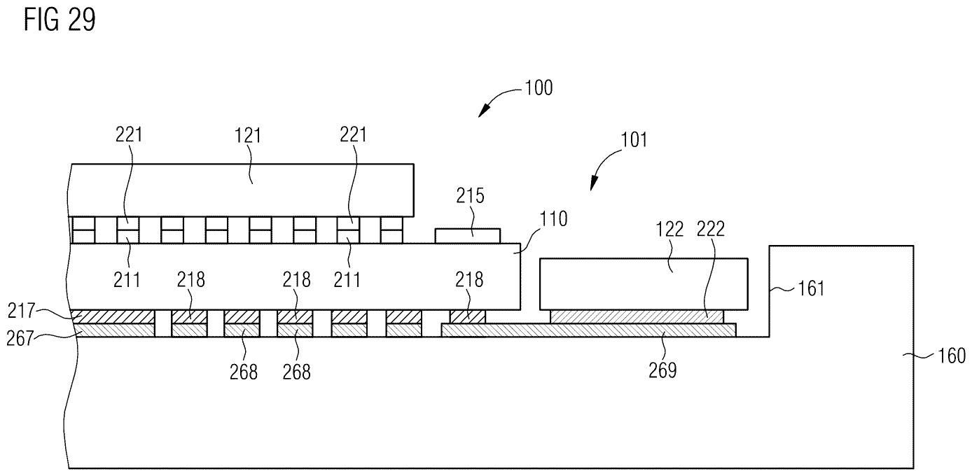

For illustration, FIGS. 27 to 29 show a plan view illustration, a rear-side illustration and a lateral sectional illustration of an optoelectronic module 100 which is configured to that effect and which represents a development of the module 100 explained with reference to FIGS. 21 to 25. In the rear view in FIG. 28, the carrier 160 is illustrated as partly see-through. In line with the configurations explained above, the electronic semiconductor chip 110 comprises front-side contact elements 210, 211, 213, 215, of which the contact elements 211, 215 are shown in FIGS. 27 and 29. With regard to the contact elements 210, 211, 213 provided for the contacting of the pixelated light-emitting semiconductor chip 121 and the light-emitting semiconductor chips 130, 131, a configuration as shown in FIG. 20 is present. In this case, the semiconductor chips 130, 131 are additionally contacted by way of contact elements 260 of the carrier 160.

As is shown in FIGS. 28 and 29, the electronic semiconductor chip 110 furthermore comprises rear-side contact elements 217, 218. In accordance with the configuration depicted, the contact elements 218 are configured in circular fashion and the contact elements 217 comprise an elongate shape. The carrier 160, comprising a depression 161 in the configuration shown here, comprises a contact structure with contact elements 267, 268, 269, which is coordinated with the rear-side contact structure of the electronic semiconductor chip 110, as is illustrated in FIGS. 28 and 29. The contact elements 267, 268, 269 are located in the region of the bottom of the depression 161 of the carrier 160, as is shown in FIG. 29. Only the contact elements 269 of the carrier 160 are depicted in FIG. 28, and hereinafter these are also referred to as extension contact elements 269. Another possible designation is fan-out contacts. In the case of the electronic semiconductor chip 110 mounted within the depression 161 on the carrier 160, the contact elements 217 and a portion of the contact elements 218 of the semiconductor chip 110 are electrically connected to opposite contact elements 267, 268 of the carrier 160, and contact elements 218 present at the edge of the semiconductor chip 110 are electrically connected to the extension contact elements 269 of the carrier 160 that are opposite them, by way of a connection medium.

It is possible to use the contact elements 267, 268 of the carrier 160 and the contact elements 217, 218 of the electronic semiconductor chip 110 that are connected to them for the electrical supply of the semiconductor chip 110 and for carrying out data communication with the semiconductor chip 110. In this case, the carrier 160 may comprise at the front side outside the depression 161, for example, further, externally contactable contact elements (for example contact elements 265, as shown in FIG. 11), which are electrically connected to the contact elements 267, 268 by way of suitable conductor structures of the carrier 160 (not illustrated).

As becomes clear from FIGS. 28 and 29, the extension contact elements 269 of the carrier 160 comprise an elongate shape and project laterally beyond the electronic semiconductor chip 110 at the rear side of the semiconductor chip 110. At this location, within the depression 161 of the carrier 160 laterally next to the electronic semiconductor chip 110, a further component of the optoelectronic component structure 101 is mounted on the carrier 160 and is contacted by the extension contact elements 269, such that the relevant component may be electrically driven and have corresponding electrical potentials applied to it by the semiconductor chip 110 by way of the extension contact elements 269. As is indicated by dashed lines in FIGS. 27 and 28 and is shown in FIG. 29, the component contacted by way of the extension contact elements 269 may be a further pixelated light-emitting semiconductor chip 122, as has been explained with reference to FIG. 26. In this case, the separate elongate contact elements 222 of the semiconductor chip 122 are electrically connected to extension contact elements 269 of the carrier 160 by way of a connection medium. The (not shown) continuous contact element 220 of the semiconductor chip 122 may be electrically connected to one or more extension contact elements 269 of the carrier 160 in a corresponding manner. In this configuration, by way of the semiconductor chip 122, a light emission may be caused in a regional lateral to the electronic semiconductor chip 110. Some other light-emitting semiconductor chip may also be used instead of the semiconductor chip 122.

In the case of the optoelectronic module 100 shown in FIGS. 27 to 29, two mutually offset contacting planes are present for a contacting of the optoelectronic component structure 101. One contacting plane is formed by the front-side contact elements 210, 211, 213 of the electronic semiconductor chip 110 and the contact elements 260 of the carrier 160, and a further contacting plane is formed by the extension contact elements 269 of the carrier 160. In a corresponding manner, the optoelectronic component structure 101 comprises components arranged in offset planes, i.e. the semiconductor chips 120, 130, 131 in one plane and the semiconductor chip 122 in a further plane.

For the optoelectronic module 100 explained with reference to FIGS. 27 to 29, too, a multipartite configuration corresponding to FIG. 7 may be considered with regard to the carrier 160. In this case, the contact elements 267, 268, 269 of the carrier 160 may be provided on the base part 162, and the contact elements 260 of the carrier 160 that are used for the contacting of the semiconductor chips 130, 131 may be provided on the further carrier part 163. Furthermore, the electronic semiconductor chip 110 together with the component or semiconductor chip 122 contacted by way of the extension contact elements 269 may be mounted on the base part 162 (the drawings do not depict this).

In accordance with the configurations of the optoelectronic module 100 illustrated in FIG. 5 and subsequent figures, electrical potentials applied to the optoelectronic component structure 101 are provided and hence a current supply of the component structure 101 is effected by the electronic semiconductor chip 110. If high-current operation, for example with a current intensity of a number of amperes, is provided for one or more components of the component structure 101, this may be realized by way of a high-current design of the semiconductor chip 110. Alternatively, a high-current supply of one or more components may be performed by way of the carrier 160 instead of by way of the electronic semiconductor chip 110. As a result, a high-current design of the semiconductor chip 110 may be obviated, and the semiconductor chip 110 may be realized cost-effectively.

For illustration, FIG. 30 shows a lateral illustration of an optoelectronic module 100 configured to that effect. The module 100 comprises a construction comparable to FIG. 6, wherein the optoelectronic component structure 101 in accordance with the configuration depicted here comprises, besides the pixelated light-emitting semiconductor chip 120, a plurality of or two light-emitting semiconductor chips 130 mounted on the carrier 160. The semiconductor chips 130 may be high-power LEDs, that is to say relatively powerful and light-intensive light-emitting diode chips. For each of the light-emitting semiconductor chips 130, the carrier 160 comprises two contact elements 260, 261 which are electrically connected to rear-side contact elements 230, 231 of the semiconductor chips 130 by way of a connection medium. The contact elements 260, 261 are part of an electrical current feed device 167 of the carrier 160 illustrated schematically in FIG. 30, said current feed device furthermore comprising current feed lines 166 and switches 165 besides the contact elements 260, 261. In the present case, the switches 165 are arranged in line paths assigned to the contact elements 261. The switches 165 may be realized in the form of transistors such as, for example, MOSFETS (metal-oxide-semiconductor field-effect transistor). By way of the current feed device 167, the semiconductor chips 130 or the contact elements 230, 231 thereof may be connected to an external current source 175 separately from one another for high-current operation. The carrier 160 or the current feed device 167 thereof is suitably connected to the current source 175 for this purpose.

In the case of the optoelectronic module 100 in FIG. 30, too, the control of operation of the light-emitting semiconductor chips 130 is performed by the electronic semiconductor chip 110. For this purpose, the electronic semiconductor chip 110 is electrically connected to the switches 165 by way of control lines 170. In this way, activation and deactivation of the current supply of the light-emitting semiconductor chips 130 and hence of the light emission from the semiconductor chips 130 may be caused by corresponding driving of the switches 165 by way of the electronic semiconductor chip 110.

The control lines 170 may be conductor structures of the carrier 160 which are electrically connected to the electronic semiconductor chip 110 in a suitable manner. In this case, the control lines 170, in a manner comparable to the conductor tracks 270 shown in FIG. 11, may be connected to contact elements 215 of the electronic semiconductor chip 110 by way of connection structures 181. The current feed lines 166 of the current feed device 167 may also be realized by conductor structures of the carrier 160. For the case where, with regard to the optoelectronic module 100 in FIG. 30, a multipartite configuration of the carrier 160 corresponding to FIG. 7 is provided, constituent parts such as the current feed device 167 and the control lines 170 may be formed in the further carrier part 163, for example.

The optoelectronic component structure 101 of the optoelectronic module 100 may be realized in such a way that a light emission may be effected in a region laterally enclosing the electronic semiconductor chip 110. This is the case for example for a further configuration of the optoelectronic module 100, shown in a plan view in FIG. 31. In this case, the component structure 101 comprises a pixelated light-emitting semiconductor chip 120 arranged on the electronic semiconductor chip 110, and a plurality of light-emitting semiconductor chips 130 located next to the semiconductor chip 120 and enclosing the semiconductor chip 120. The pixelated light-emitting semiconductor chip 120 may correspond to the electronic semiconductor chip 110 in terms of the lateral dimensions, such that the electronic semiconductor chip 110, as shown in FIG. 31, may be concealed by the semiconductor chip 120. The semiconductor chips 130 may be mounted on the carrier 160 in a manner corresponding to FIG. 6.

Further configurations may be considered for the optoelectronic module 100. By way of example, the optoelectronic module 100 may be realized in such a way that the optoelectronic component structure 101 comprises, additionally or instead of a pixelated light-emitting semiconductor chip 120, a multiplicity of light-emitting components or semiconductor chips arranged on the electronic semiconductor chip 110. The components may comprise relatively small lateral dimensions, and may be for example semiconductor chips 130 with rear-side contact elements 230, 231. In this case, the electronic semiconductor chip 110 comprises a contact structure coordinated therewith comprising contact elements for the mounting of the components or semiconductor chips 130. In a manner corresponding to FIG. 5, the semiconductor chip 110 may comprise contact elements 212, 213 in this case.

Furthermore, configurations of the optoelectronic module 110 are conceivable in which the optoelectronic component structure 101 is additionally extended by a sensor technology and is configured for enabling a radiation detection. This may serve the purpose for example of capturing ambient light in order to carry out the light emission-controlled by the electronic semiconductor chip 110-from the component structure 101 in a manner coordinated with the ambient light respectively present. Furthermore, it is possible to carry out an optical communication based on light emission and radiation detection. In this case, it is possible to switch between a transmitting and receiving mode, in which a light emission and a radiation detection take place.

In order to illustrate the aforementioned features, FIGS. 32 and 33 show a plan view illustration and a lateral sectional illustration of an optoelectronic module 100 realized to that effect. FIG. 32 schematically shows three regions 310, 311, 312 of the module 100, wherein the regions 310, 311 are provided for light emission and the region 312 is provided for radiation detection. In the region 310, the electronic semiconductor chip 110 used for controlling operation of the optoelectronic component structure 101 is also arranged on the carrier 160. In the region 310, furthermore, a plurality of light-emitting components, for example semiconductor chips 130 as shown in FIG. 33, are mounted on the semiconductor chip 110 and optionally also on the carrier 160. In the region 311, in which a light emission may take place lateral to the electronic semiconductor chip 110, likewise a plurality of light-emitting components, for example semiconductor chips 130 as shown in FIG. 33, are mounted only on the carrier 160. A configuration corresponding to FIG. 6 may be present in this case. In the regions 310, 311, the semiconductor chips 130 may be arranged next to one another in matrixlike fashion in the form of rows and columns (not illustrated).

In the region 312 provided for radiation detection, the optoelectronic component structure 101 furthermore comprises at least one radiation-detecting optoelectronic component 139 arranged on the carrier 160. The radiation-detecting component 139 may be a semiconductor chip comprising a photodiode structure. Moreover, the radiation-detecting component 139 may comprise rear-side contact elements 230, 231, and may be mounted on the carrier 160 in a manner corresponding to FIG. 6. With regard to the regions 311, 312, as indicated in FIG. 33, electrical connections between the components 130, 139 and the electronic semiconductor chip 110 are established, such that the semiconductor chip 110 may control the operation of the components 130, 139 and measurement signals generated by the radiation-detecting component 139 may be communicated to the semiconductor chip 110.

Alternatively, there is the possibility of performing a radiation detection using the carrier 160 itself, by virtue of the carrier 160 being realized with one or more integrated photodiodes. For illustration, FIG. 34 shows a lateral illustration of the optoelectronic module 100 comprising a modified design by comparison with FIG. 33. In this case, the carrier 160 comprises at least one integrated photodiode 169 in the radiation-detecting region 312. The photodiode 169 is suitably electrically connected to the electronic semiconductor chip 110, such that measurement signals of the photodiode 169 may be communicated to the semiconductor chip 110. The electrical connection may be established by way of conductor structures of the carrier 160 and also, in a manner corresponding to FIG. 11, connection structures 181.

One possible modification of the configuration in FIGS. 32 to 34 may consist in providing light-emitting semiconductor chips comprising a vertical design for the region 310, and therefore configuring the region 310 for example in a manner corresponding to FIGS. 14 and 15.

The configurations of the optoelectronic module 100 explained with reference to the preceding figures may be modified to the effect that a radiation detection is likewise possible. By way of example, with regard to FIGS. 10, 12, 13, 14, 19, 21, 27 and 31, it is conceivable for one of the semiconductor chips 130, the semiconductor chip 131, the semiconductor chip 132 or one of the semiconductor chips 140, 141, 142 to be realized in the form of a radiation-detecting semiconductor chip, or for the carrier 160 to comprise at least one integrated photodiode 169.

Besides the embodiments described above and depicted in the figures, further embodiments are conceivable which may comprise further modifications and/or combinations of features.

It is possible to realize the carrier 160 with different materials than those mentioned above. To that effect, the carrier 160 may also be realized for example at least partly in the form of a printed circuit board (PCB) or flexible printed circuit board.

Further modifications (not shown) may consist in the optoelectronic module 100 comprising an optoelectronic component structure 101 comprising a different number and/or geometric arrangement of optoelectronic components or semiconductor chips. This includes a configuration of the optoelectronic component structure 101 comprising only one light-emitting optoelectronic component. Referring to FIG. 21, it is conceivable for example for the component structure 101 to comprise only the pixelated light-emitting semiconductor chip 121 projecting beyond the electronic semiconductor chip 101. Referring to FIG. 27, a plurality of components arranged next to the electronic semiconductor chip 110 and contacted by way of extension contact elements 269 may be provided, for example. Referring to FIG. 30, the current feed device 167 of the carrier 160 may be configured for the electrical supply of a different number of components or semiconductor chips 130, including only one component.

With the use of one or more light-emitting semiconductor chips 140, 141, 142 realized in accordance with a vertical design, as has been explained with reference to FIGS. 14 to 16, modifications that are not illustrated may consist in arranging the semiconductor chip(s) 140, 141, 142 for example only on the electronic semiconductor chip 110 or only on the carrier 160. In this case, a rear-side contact element of a semiconductor chip 140, 141, 142 may also be contacted by a contact element of the carrier 160, and a front-side contact element of a semiconductor chip 140, 141, 142 may be electrically connected to a contact element of the electronic semiconductor chip 110 or carrier 160 by way of a contact layer or a bond wire.

With regard to the light-emitting optoelectronic components or semiconductor chips used, other designs may be used aside from the designs described and shown in the figures. By way of example, the optoelectronic component structure 101 may comprise not just at least one light-emitting diode chip, but alternatively or additionally a laser diode chip or surface emitter (VCSEL, vertical-cavity surface emitting laser). Referring for example to FIG. 19 or 30, one or more semiconductor chips 130 may be such surface emitters.

Furthermore, it is possible not just to use semiconductor chips in the form of thin-film chips as shown in FIGS. 1 and 2. Designs (not shown) are also possible in which the semiconductor chips comprise a chip substrate, for example composed of sapphire, in addition to a semiconductor layer sequence 150.

Furthermore, it is conceivable for the optoelectronic component structure 101 to comprise one or more packaged optoelectronic components additionally or instead of one or more semiconductor chips. Such components may comprise one or more light-emitting semiconductor chips provided with a package. Moreover, the components may comprise rear-side contact elements, for example. In this regard, for example, the components 130 may be such packaged components, and may be mounted on the electronic semiconductor chip 110 and/or carrier 160 in a manner corresponding to FIGS. 5, 6, 8 and 9.

The optoelectronic module 100 may furthermore comprise further constituent parts that are not illustrated. These may include for example one or more optics units or optical components such as lenses, for example. Such components may be suitably secured on the carrier 160.

Besides an application in a headlight, the optoelectronic module 100 may be used or configured for other applications. These may include for example a projector, an optical communication module or a display device such as a microdisplay, for example. With respect to the latter, the optoelectronic component structure 101 may be configured for generating different-colored light radiations. For this purpose, the component structure 101 may comprise for example a plurality of light-emitting components, for example semiconductor chips 130, arranged next to one another, a portion of these in each case being configured for generating a red light radiation, a green light radiation and a yellow light radiation. Furthermore, in line with the approaches above, one portion of the light-emitting components may be arranged at least on the electronic semiconductor chip 110, and another portion of the light-emitting components may be arranged at least on the carrier 160 lateral to the semiconductor chip 110 (not illustrated).

One exemplary production method, not illustrated, with the aid of which a plurality of optoelectronic modules 100 may be produced, and in which various placement methods may be used, may be carried out as follows. An ASIC wafer is provided, which later will yield a plurality of electronic semiconductor chips 110. Light-emitting semiconductor chips or LED chips, for example pixelated light-emitting semiconductor chips 120 and optionally further semiconductor chips, are placed on the ASIC wafer and the latter is subsequently singulated, such that chip components comprising an electronic semiconductor chip 110 and one or more light-emitting semiconductor chips arranged thereon are provided. The chip components are arranged on a submount wafer, which later will yield carriers 160. This may be effected by way of a chip-to-wafer method. The submount wafer may comprise depressions 161 in which the chip components or the electronic semiconductor chips 110 thereof are arranged. Further light-emitting semiconductor chips are subsequently placed on the submount wafer. In this case, a multiplicity of semiconductor chips may be jointly arranged on the submount wafer, for example by way of a stamping technique. Depending on the design of the semiconductor chips, further steps may take place, for example forming planar contact layers 187 in the case where semiconductor chips 140, 141, 142 are used. Optionally, further elements such as optical elements may be arranged on the submount wafer. The submount wafer is subsequently singulated, whereby separate optoelectronic modules 100 are provided. Such a module 100 may then be inserted for example into a housing of a headlight or a projection or headlight module.

Although the invention has been more specifically illustrated and described in detail by way of preferred exemplary embodiments, nevertheless the invention is not restricted by the examples disclosed and other variations may be derived therefrom by a person skilled in the art, without departing from the scope of protection of the invention.

### LIST OF REFERENCE SIGNS

100 Optoelectronic module
101 Optoelectronic component structure
110 Electronic semiconductor chip
111 IC logic
115 Switch
120 Semiconductor chip
121 Semiconductor chip
122 Semiconductor chip
125 Light-emitting region
130 Semiconductor chip
131 Semiconductor chip
132 Semiconductor chip
139 Semiconductor chip
140 Semiconductor chip
141 Semiconductor chip
142 Semiconductor chip
150 Semiconductor layer sequence
151 Semiconductor region
152 Active zone
153 Semiconductor region
155 Pixel
157 Via
159 Conversion layer
160 Carrier
161 Depression
162 Base part
163 Carrier part
165 Switch
166 Current feed line
167 Current feed device
169 Photodiode
170 Control line
175 Current source
180 Connection medium
181 Connection structure
185 Bond wire
187 Contact layer
190 Thermal connection structure
191 Insulation layer
192 Connection element
201 Contact element
202 Contact element
210 Contact element
211 Contact element
212 Contact element
213 Contact element
215 Contact element
217 Contact element
218 Contact element
220 Contact element
221 Contact element
222 Contact element
230 Contact element
231 Contact element
260 Contact element
261 Contact element
265 Contact element
267 Contact element
268 Contact element
269 Extension contact element
270 Conductor track
271 Conductor track
300 Region
301 Region
310 Region
311 Region
312 Region
320 Overlap region
330 Level difference
350 Light radiation
351 Primary radiation

1. An optoelectronic module comprising an optoelectronic component structure for light emission with at least one optoelectronic component, an electronic semiconductor chip for controlling operation of the optoelectronic component structure, and a carrier,
wherein the electronic semiconductor chip is arranged on the carrier,
wherein the optoelectronic component structure is arranged at least on the electronic semiconductor chip, and
wherein the optoelectronic component structure is configured to cause the light emission in a region covering the electronic semiconductor chip and in a region not covering the electronic semiconductor chip and lateral to the electronic semiconductor chip.

2. The optoelectronic module according to claim 1,
wherein the optoelectronic component structure comprises an optoelectronic component which is arranged on the electronic semiconductor chip and the carrier and covers the electronic semiconductor chip and the carrier lateral to the electronic semiconductor chip in a region.

3. The optoelectronic module according to claim 1,
wherein the optoelectronic component structure comprises an optoelectronic component which projects laterally beyond the electronic semiconductor chip, thereby covers the carrier in a region lateral to the electronic semiconductor chip and is thermally conductively connected to the carrier in this region.

4. The optoelectronic module according to claim 1,
wherein the optoelectronic component structure comprises an optoelectronic component which is arranged at least on the electronic semiconductor chip and covers at least the electronic semiconductor chip in a region, and wherein the optoelectronic component structure comprises at least one further optoelectronic component which is arranged at least on the carrier and covers at least the carrier in a region lateral to the electronic semiconductor chip.

5. The optoelectronic module according to claim 1,
wherein the optoelectronic component structure comprises an optoelectronic component with contact elements at a rear side which are electrically connected to opposite contact elements of the electronic semiconductor chip.

6. The optoelectronic module according to claim 1,
wherein the optoelectronic component structure comprises an optoelectronic component in a form of a pixelated light-emitting semiconductor chip arranged on the electronic semiconductor chip, and wherein the pixelated light-emitting semiconductor chip comprises contact elements at a rear side which are electrically connected to opposite contact elements of the electronic semiconductor chip.

7. The optoelectronic module according to claim 6,
wherein the pixelated light-emitting semiconductor chip projects laterally beyond the electronic semiconductor chip and comprises at its rear side contact elements which project laterally beyond the electronic semiconductor chip and which are electrically connected to opposite contact elements of the electronic semiconductor chip.

8. The optoelectronic module according to claim 1,
wherein the optoelectronic component structure comprises an optoelectronic component with contact elements at a rear side, of which contact elements one rear-side contact element of the optoelectronic component is electrically connected to an opposite contact element of the electronic semiconductor chip and a further rear-side contact element of the optoelectronic component is electrically connected to an opposite contact element of the carrier.

9. The optoelectronic module according to claim 1,
wherein the optoelectronic component structure comprises an optoelectronic component with contact elements at a rear side which are electrically connected to opposite contact elements of the carrier.

10. The optoelectronic module according to claim 1,
wherein the optoelectronic component structure comprises an optoelectronic component with a contact element at a front side and a contact element at a rear side, wherein the contact element at the rear side of the optoelectronic component is electrically connected to an opposite contact element of the electronic semiconductor chip and the contact element at the front side of the optoelectronic component is electrically connected to a contact element of the carrier.

11. The optoelectronic module according to claim 10,
wherein the contact element at the front side of the optoelectronic component and the contact element of the carrier are electrically connected by way of a contact layer.

12. The optoelectronic module according to claim 1,
wherein the electronic semiconductor chip comprises contact elements at a front side and at a rear side.

13. The optoelectronic module according to claim 1,
wherein the carrier comprises extension contact elements which are electrically connected to contact elements of the electronic semiconductor chip at a rear side of the electronic semiconductor chip and project laterally beyond the electronic semiconductor chip at the rear side of the electronic semiconductor chip, and wherein the optoelectronic component structure comprises an optoelectronic component which is arranged laterally next to the electronic semiconductor chip and comprises contact elements electrically connected to the extension contact elements.

14. The optoelectronic module according to claim 1,
wherein the carrier comprises a current feed device for an electrical current supply of an optoelectronic component of the optoelectronic component structure, and wherein the current feed device comprises a switching element for activating the electrical current supply, said switching element being electrically connected to the electronic semiconductor chip and controllable by the electronic semiconductor chip.

15. The optoelectronic module according to claim 1,
wherein the carrier comprises a depression with the electronic semiconductor chip arranged therein.

16. The optoelectronic module according to claim 1,
wherein the carrier comprises a base part and a further carrier part, wherein the electronic semiconductor chip is arranged on the base part, and wherein the further carrier part is arranged on the base part laterally next to the electronic semiconductor chip.

17. The optoelectronic module according to claim 1,
wherein the carrier comprises at least one of the following carrier materials: silicon, ceramic.

18. The optoelectronic module according to claim 1, comprising at least one of:
the optoelectronic component structure comprises a radiation-detecting optoelectronic component; and/or
the carrier comprises an integrated photodiode.

19. (canceled)

20. An optoelectronic module comprising an optoelectronic component structure for light emission with at least one optoelectronic component, an electronic semiconductor chip for controlling operation of the optoelectronic component structure, and a carrier,
wherein the electronic semiconductor chip is arranged on the carrier,
wherein the optoelectronic component structure is arranged at least on the electronic semiconductor chip,
wherein the optoelectronic component structure is configured to cause the light emission in a region covering the electronic semiconductor chip and in a region not covering the electronic semiconductor chip and lateral to the electronic semiconductor chip,
wherein the optoelectronic component structure comprises an optoelectronic component in a form of a pixelated light-emitting semiconductor chip arranged on the electronic semiconductor chip,
wherein the pixelated light-emitting semiconductor chip projects laterally beyond the electronic semiconductor chip and comprises at its rear side contact elements which project laterally beyond the electronic semiconductor chip and which are electrically connected to opposite contact elements of the electronic semiconductor chip, and
wherein the pixelated light-emitting semiconductor chip comprises pixels which project laterally beyond the electronic semiconductor chip.

21. An optoelectronic module comprising an optoelectronic component structure for light emission with at least one optoelectronic component, an electronic semiconductor chip for controlling operation of the optoelectronic component structure, and a carrier,
wherein the electronic semiconductor chip is arranged on the carrier,
wherein the optoelectronic component structure is arranged at least on the electronic semiconductor chip,
wherein the optoelectronic component structure is configured to cause the light emission in a region covering the electronic semiconductor chip and in a region not covering the electronic semiconductor chip and lateral to the electronic semiconductor chip,
wherein the carrier comprises a current feed device for an electrical current supply of an optoelectronic component of the optoelectronic component structure,
wherein the current feed device comprises conductor structures and contact elements electrically connected to contact elements of the optoelectronic component, and
wherein the current feed device comprises a switching element for activating the electrical current supply, said switching element being electrically connected to the electronic semiconductor chip and controllable by the electronic semiconductor chip.
